(19) United States
(12) Patent Application Publication
(10) Pub. No.: US 2012/0176393 A1
(43) Pub. Date: Jul. 12, 2012

(54) MEMORY DEVICE, DISPLAY DEVICE EQUIPPED WITH MEMORY DEVICE, DRIVE METHOD FOR MEMORY DEVICE, AND DRIVE METHOD FOR DISPLAY DEVICE

(75) Inventors: Hiroyuki Ohkawa, Osaka-shi (JP); Yasushi Sasaki, Osaka-shi (JP); Yuhichiroh Murakami, Osaka-shi (JP); Shige Furuta, Osaka-shi (JP); Seijirou Gyouten, Osaka-shi (JP); Shuji Nishi, Osaka-shi (JP)

(73) Assignee: SHARP KABUSHIKI KAISHA, Osaka-shi, Osaka (JP)

(21) Appl. No.: 13/395,977

(22) PCT Filed: Apr. 23, 2010
(86) PCT No.: PCT/JP2010/057272

§ 371 Date: Mar. 14, 2012

(30) Foreign Application Priority Data
Sep. 16, 2009 (JP) 2009-215063

(51) Int. Cl. G09G 5/36; G11C 5/02

(52) U.S. Cl. 345/560; 365/51

(57) ABSTRACT

Provided is a memory device that allows an amount of leakage into a first retaining section to which a binary logic level is written to be balanced between different circuit states. A predetermined period is set in which in a state where a first control section turns off an output element, (i) a first retaining section and a second retaining section retain an identical binary logic level, (ii) an electric potential of a voltage supply is set to one of a first electric potential level and a second electric potential level, (iii) the other one of the first electric potential level and the second electric potential level is supplied from a column driver to a fourth wire, and (iv) subsequently the fourth wire is shifted to a floating state.

### TECHNICAL FIELD

The present invention relates to a memory device which is capable of retaining data.

### BACKGROUND ART

A liquid crystal display device which displays a still image is exemplified by a liquid crystal display device including a pixel memory which carries out a display by temporarily retaining image data written to a pixel and carrying out a refresh operation while reversing polarities of the image data. Image data is rewritten to new image data in a pixel every one frame via a data signal line in a normal operation in which a multi-gradation moving image is displayed, whereas image data retained in a pixel memory is used in a memory operation in which a still image is displayed. In view of this, it is unnecessary to supply rewriting image data to a data line while the refresh operation is being carried out.

Accordingly, electric power consumption can be reduced since it is possible in the memory operation to stop an operation of a circuit which drives a scanning signal line and a data signal line. Electric power consumption can also be reduced by a reduction in number of times of charge and discharge of the data signal line having a large capacity and without the need of transmitting, to a controller, image data corresponding to a memory operation period.

Accordingly, a pixel which carries out the memory operation is frequently used for an image display such as a standby display of a mobile phone, the image display being strongly required to be carried out with lower electric power consumption.

FIG. 27 illustrates only a memory circuit part of each pixel structure of a liquid crystal display device including such a pixel memory. In order to cause the each pixel structure to function also as a pixel of the liquid crystal display device, it is only necessary to assume that a liquid crystal capacitor C1c is added to the each pixel structure (see a broken line in FIG. 27). Such a pixel structure is equivalent to, for example, a pixel structure disclosed in Patent Literature 1.

A memory circuit MR100 serving as the memory circuit part includes a switching circuit SW100, a first data retaining section DS101, a data transfer section TS100, a second data retaining section DS102, and a refresh output control section RS100.

The switching circuit SW100 includes a transistor N100 which is an N-channel TFT. The first data retaining section DS101 includes a capacitor Ca100. The data transfer section TS100 includes a transistor N101 which is an N-channel TFT. The second data retaining section DS102 includes a capacitor Cb100. The refresh output control section RS100 includes an inverter INV100 and a transistor N103 which is an N-channel TFT. The inverter INV100 includes a transistor P100 which is a P-channel TFT and a transistor N102 which is an N-channel TFT.

As wires for driving each memory circuit MR100, a data transfer control line DT100, a switch control line SC100, a High voltage supply line PH100, a Low voltage supply line PL100, a refresh output control line RC100, and a capacitor wire CL100 are provided for each row of a pixel matrix, and a data input line IN100 is provided for each column of the pixel matrix.

One and the other of drain/source terminals of a field-effect transistor such as a TFT mentioned above are referred to as a first drain/source terminal and a second drain/source terminal, respectively. Note, however, that the first drain/source terminal and the second drain/source terminal between which a drain terminal and a source terminal are constantly fixed in accordance with a direction in which a current flows are referred to as the drain terminal and the source terminal, respectively. The transistor N100 has a gate terminal which is connected to the switch control line SC100, the first drain/source terminal which is connected to the data input line IN100, and the second drain/source terminal which is connected to a node PIX that is one end of the capacitor Ca100. The other end of the capacitor Ca100 is connected to the capacitor wire CL100.

The transistor N101 has a gate terminal which is connected to the data transfer control line DT100, a first drain/source terminal which is connected to the node PIX, and a second drain/source terminal which is connected to a node MRY that is one end of the capacitor Cb100. The other end of the capacitor Cb100 is connected to the capacitor wire CL100.

An input terminal IP of the inverter INV100 is connected to the node MRY. The transistor P100 has a gate terminal which is connected to the input terminal IP of the inverter INV100, a source terminal which is connected to the High voltage supply line PH100, and a drain terminal which is connected to an output terminal OP of the inverter INV100. The transistor N102 has a gate terminal which is connected to the input terminal IP of the inverter INV100, a drain terminal which is connected to the output terminal OP of the inverter INV100, and a source terminal which is connected to the Low voltage supply line PL100. The transistor N103 has a gate terminal which is connected to the refresh output control line RC100, a first drain/source terminal which is connected to the output terminal OP of the inverter INV100, and a second drain/source terminal which is connected to the node PIX.

Note that, in a case where a pixel structure is constituted as a pixel by adding the liquid crystal capacitor C1c to the memory circuit MR100, the liquid crystal capacitor C1c is connected between the node PIX and a common electrode COM.

Next, operation of the memory circuit MR100 is described below with reference to FIG. 28.

It is assumed in FIG. 28 that the memory circuit MR100 is in a memory operation mode such as a standby state of a mobile phone. An electric potential of binary levels which are High (an active level) and Low (a non-active level) is applied from a driving circuit (not illustrated) to each of the data transfer control line DT100, the switch control line SC100, and the refresh output control line RC100. The High and Low binary levels of a voltage may be individually set for each of these lines. The High and Low binary logic levels are supplied from the driving circuit (not illustrated) to the data input line IN100. An electric potential to be supplied from the High voltage supply line PH100 is equivalent to the High binary logic level, and an electric potential to be supplied from the Low voltage supply line PL100 is equivalent to the Low binary logic level. An electric potential to be supplied from the capacitor wire CL100 may be constant or may change at a given timing. For convenience of explanation, it is assumed here that the electric potential to be supplied from the capacitor wire CL100 is constant.

A writing period T101 and a refresh period T102 are set in the memory operation mode. The writing period T101 is a period in which data to be retained in the memory circuit MR100 is written to the memory circuit MR100 and which has a period t101 and a period t102 that are successive in this order. Since line-sequential writing is carried out with respect to the memory circuit MR100 in the writing period T101, the period t101 is set so that a period t101 of one row does not overlap a period t101 of another row. Accordingly, a start timing of the writing period T101 varies according to the row. An end timing of the period t102, i.e., an end timing of the writing period T101 is identical in all the rows. The refresh period T102 is a period in which the data written to the memory circuit MR100 in the writing period T101 is retained while being refreshed and which has a period t103 through a period t110 that start concurrently in all the rows and are successive in this order.

The switch control line SC100 has a High electric potential in the period t101 of the writing period T101. Each of the data transfer control line DT100 and the refresh output control line RC100 has a Low electric potential. This causes the transistor N100 to turn on. Therefore, a data electric potential (High here) supplied to the data input line IN100 is written to the node PIX. The switch control line SC100 has a Low electric potential in the period t102. This causes the transistor N100 to turn off. Therefore, an electric charge corresponding to the written data electric potential is retained in the capacitor Ca100.

Note here that, in a case where the memory circuit MR100 is constituted only by the capacitor Ca100 and the transistor N100, the node PIX is floating while the transistor N100 is off. In this case, ideally, the electric charge is retained in the capacitor Ca100 so that an electric potential of the node PIX is maintained at High. However, in reality, an off-leakage current occurs in the transistor N100. This causes the electric charge of the capacitor Ca100 to gradually leak to an outside of the memory circuit MR100. The leak of the electric charge of the capacitor Ca100 causes the electric potential of the node PIX to change. Therefore, in a case where the electric charge leaks for a long time, the electric potential of the node PIX changes to an extent that the written data electric potential loses its original function.

In view of the circumstances, the data transfer section TS100, the second data retaining section DS102, and the refresh output control section RS100 are arranged to function to refresh the electric potential of the node PIX, so as to prevent the written data from being lost.

Therefore, the refresh period T102 comes next. The data transfer control line DT100 has a High electric potential in the period t103. This causes the transistor N101 to turn on. Therefore, the capacitor Cb100 is connected in parallel to the capacitor Ca100 via the transistor N101. The capacitor Ca100 is set to have a larger capacitance than the capacitor Cb100. Accordingly, movement of the electric charge between the capacitor Ca100 and the capacitor Cb100 causes an electric potential of the node MRY to be High. A positive electric charge moves from the capacitor Ca100 via the transistor N101 to the capacitor Cb100 until the electric potential of the node PIX becomes equivalent to the electric potential of the node MRY. This causes the electric potential of the node PIX to be lower by a slight amount of voltage of ΔV1 than that obtained in the period t102. However, the electric potential of the node PIX falls within a range of a High electric potential. The data transfer control line DT100 has a Low electric potential in the period t104. This causes the transistor N101 to turn off. Therefore, the electric charge is retained in the capacitor Ca100 so that the electric potential of the node PIX is maintained at High, and the electric charge is retained in the capacitor Cb100 so that the electric potential of the node MRY is maintained at High.

The refresh output control line RC100 has a High electric potential in the period t105. This causes the transistor N103 to turn on. Therefore, the output terminal OP of the inverter INV100 is connected to the node PIX. Since a reverse electric potential (Low here) to the electric potential of the node MRY is supplied to the output terminal OP, the node PIX is charged at the reverse electric potential. The refresh output control line RC100 has a Low electric potential in the period t106. This causes the transistor N103 to turn off. Therefore, the electric charge is retained in the capacitor Ca100 so that the electric potential of the node PIX is maintained at the reverse electric potential.

The data transfer control line DT100 has a High electric potential in the period t107. This causes the transistor N101 to turn on. Therefore, the capacitor Cb100 is connected in parallel to the capacitor Ca100 via the transistor N101. Accordingly, movement of the electric charge between the capacitor Ca100 and the capacitor Cb100 causes the electric potential of the node MRY to be Low. A positive electric charge moves from the capacitor Cb100 via the transistor N101 to the capacitor Ca100 until the electric potential of the node MRY becomes equivalent to the electric potential of the node PIX. This causes the electric potential of the node PIX to be higher by a slight amount of voltage of ΔV2 than that obtained in the period t106. However, the electric potential of the node PIX falls within a range of a Low electric potential.

The data transfer control line DT100 has a Low electric potential in the period t108. This causes the transistor N101 to turn off. Therefore, the electric charge is retained in the capacitor Ca100 so that the electric potential of the node PIX is maintained at Low, and the electric charge is retained in the capacitor Cb100 so that the electric potential of the node MRY is maintained at Low.

The refresh output control line RC100 has a High electric potential in the period t109. This causes the transistor N103 to turn on. Therefore, the output terminal OP of the inverter INV100 is connected to the node PIX. Since a reverse electric potential (High here) to the electric potential of the node MRY is supplied to the output terminal OP, the node PIX is charged at the reverse electric potential. The refresh output control line RC100 has a Low electric potential in the period t110. This causes the transistor N103 to turn off. Therefore, the electric charge is retained in the capacitor Ca100 so that the electric potential of the node PIX is maintained at the reverse electric potential.

Thereafter, the period t103 through the period t110 are repeated in the refresh period T102 until the next writing period T101 comes. In the period t105, the electric potential of the node PIX is refreshed to the reverse electric potential. In the period t109, the electric potential of the node PIX is refreshed to the electric potential obtained during writing. Note that, in a case where the data electric potential of Low is written to the node PIX in the period t101 of the writing period T101, an electric potential waveform of the node PIX is obtained by reversing an electric potential waveform of FIG. 28.

As described earlier, the memory circuit MR100 is arranged such that in accordance with a data inversion method, written data is retained while being refreshed. Assume that the liquid crystal capacitor C1c is added to the memory circuit MR100. In a case where an electric potential of the common electrode COM is reversed between High and Low at a timing at which data is refreshed, black display data or white display data can be refreshed while its polarities are being reversed.

### CITATION LIST

### Patent Literature 1

Japanese Patent Application Publication, Tokukai, No. 2002-229532 A (Publication Date: Aug. 16, 2002)

### SUMMARY OF INVENTION

### Technical Problem

FIG. 29 illustrates the arrangement of the memory circuit MR100 of FIG. 27 again. In FIG. 29, the node PIX, the node MRY, the output terminal of the inverter INV100 are illustrated as a node A, a node B, and a node C, respectively. A driving circuit which supplies data to the data input line IN100 is connected to the data input line IN100 via a sampling switch SMP.

As is clear from FIG. 28, in the period t105 and the period t109 in which a refreshed electric potential is retained by turning the transistor N103 off, in a case where the node A (the node PIX) is Low, the node B (the node MRY) is High, and therefore the node C is Low, whereas in a case where the node A (the node PIX) is High, the node B (the node MRY) is Low, and therefore the node C is High. Here, the data input line IN100 can have any electric potential. However, since it is unnecessary to supply data to the data input line IN100 in the refresh period T102, the electric potential of the data input line IN100 is generally set to Low so that power consumption is suppressed.

FIG. 30 is a signal diagram obtained in a case where the memory circuit MR100 of FIG. 29 is driven with waveforms different from those of FIG. 28. In this case, in the period t201 in which a refreshed electric potential is retained by turning the transistor N103 off in the refresh period T102, any one of the following states is achieved: (i) a state in which the node A (the node PIX) is Low, the node B (the node MRY) is Low, and therefore the node C is High, (ii) a state in which the node A (the node PIX) is Low, the node B (the node MRY) is High, and therefore the node C is Low, (iii) a state in which the node A (the node PIX) is High, the node B (the node MRY) is High, and therefore the node C is Low, and (iv) a state in which the node A (the node PIX) is High, the node B (the node MRY) is Low, and therefore the node C is High.

The same is true for the subsequent periods (the period t202, the period t203, . . . ) in which a refreshed electric potential is retained by turning the transistor N103 off.

Assume that High is 5 V and Low is 0 V. In a case (1) where High, High, and Low are written into the node A, the node B, and the node C, respectively in the writing period T101, the electric potential of the node A is 0 V, the electric potential of the node B is 0 V, and the electric potential of the node C is 5 V in the period t201. Meanwhile, in a case (2) where Low, Low, and High are written into the node A, the node B, and the node C, respectively in the writing period T101, the electric potential of the node A is 5 V, the electric potential of the node B is 5 V, and the electric potential of the node C is 0 V in the period t201. That is, the node B or the node C is in a level reverse to that of the node A.

In FIG. 31, the electric potentials of the respective nodes in the period t201 which are obtained in the case (1) of FIG. 30 are shown on the circuit.

In this case, the electric potential of the node A is 0 V, the electric potential of the node B is 0 V, the electric potential of the node C is 5 V, and the electric potential of the IN100 is 0V. Accordingly, no leakage occurs in the transistor N100, and leakage occurs in the transistor N103 in a direction from the node C towards the node A. In this period, the transistor N101 is first on, and then becomes off, but virtually no leakage occurs in the transistor N101 since a transfer operation of transferring a binary logic level (High or Low) from the node A (the node PIX) to the node B (the node MRY) and an operation of finishing the transfer operation are carried out. Accordingly, the electric potential of the node A gradually rises due to the leakage of the transistor N103.

In FIG. 32, the electric potentials of the respective nodes in the period t201 which are obtained in the case (2) of FIG. 30 are shown on the circuit.

In this case, the electric potential of the node A is 5 V, the electric potential of the node B is 5 V, the electric potential of the node C is 0 V, and the electric potential of the IN100 is 0 V. Accordingly, leakage occurs in the transistor N100 in a direction from the node A towards the data input line IN100, and leakage occurs in the transistor N103 in a direction from the node A towards the node C. In this period, the transistor N101 is first on, and then becomes off, but virtually no leakage occurs in the transistor N101 since a transfer operation of transferring a binary logic level (High or Low) from the node A (the node PIX) to the node B (the node MRY) and an operation of finishing the transfer operation are carried out. Accordingly, the electric potential of the node A greatly declines due to the leakage of the transistor N100 and the transistor N103.

As described above, in a period in which a refreshed electric potential is retained by turning the transistor N103 off, i.e., by stopping the output of the refresh output control section RS100, relationship between the electric potential of the node PIX (the node A) and the electric potential of the data input line IN100 varies depending on whether the electric potential of the node PIX (the node A) is High or Low. Accordingly, an entire leakage amount from the node PIX (the node A) varies depending on differences between the electric potentials of the respective nodes. This applies also to a pixel arrangement in which a liquid crystal capacitor C1c is added to the memory circuit MR100.

As a result, depending on a state of the circuit, there occurs a problem that electric current consumption of the memory circuit MR100 and the pixel becomes very large due to a leakage amount from the node PIX (the node A). In addition, the following problem occurs. Specifically, the electric potential of the node PIX (the node A) in the pixel varies depending on the circuit state. Accordingly, just by carrying out inversion AC driving of the common electrode COM between High and Low as shown in FIG. 30, an electric potential difference between the pixel electrode and the common electrode COM, i.e., a voltage applied to liquid crystals cannot be prevented from being unevenly deviated from a set value unless the electric potential of the data input line IN100 is controlled in accordance with the circuit state. This causes a deterioration in display quality.

The present invention was attained in view of the above conventional problems, and an object of the present invention is to provide (i) a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states, (ii) a display device including the memory device, (iii) a method for driving the memory device, and (vi) a method for driving the display device.

### Solution to Problem

In order to attain the above object, a memory device of the present invention includes:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a memory device of the present invention includes:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and

a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a memory device of the present invention includes:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

In order to attain the above object, a memory device of the present invention includes:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and

a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

In order to attain the above object, a display device of the present invention includes the memory device,

the first retaining section including a liquid crystal capacitor whose pixel electrode is connected to a retaining node which retains the binary logic level of the first retaining section,

the first wire functioning also as a scanning signal line and the fourth wire functioning also as a data signal line, and

the display device carrying out display by application of a voltage to the liquid crystal capacitor that is applied by causing the row driver to drive the switching circuit via the first wire and by supplying a data signal from the column driver via the fourth wire and the switching circuit to the first retaining section.

According to the invention, the pixel electrode of the liquid crystal capacitor is connected to the retaining node of the first retaining section, the first wire functions also as a scanning signal line, and the fourth wire functions also as a data signal line. The switching circuit is capable of functioning as a selection element of a pixel. Accordingly, it is possible to produce an effect that an image can be displayed with the use of an electric potential retained in the first retaining section.

In order to attain the above object, a method of the present invention for driving a memory device is a method for driving a memory device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a method of the present invention for driving a memory device is a method for driving a memory device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and

a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a method of the present invention for driving a memory device a method for driving a memory device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section, and

a predetermined period being set in which in a state in which the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

In order to attain the above object, a method of the present invention for driving a memory device is a method for driving a memory device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and

a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

In order to attain the above object, a method of the present invention for driving a display device is a method for driving a display device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section,

the first retaining section including a liquid crystal capacitor whose pixel electrode is connected to a retaining node which retains the binary logic level of the first retaining section,

the first wire functioning also as a scanning signal line and the fourth wire functioning also as a data signal line,

the display device carrying out display by application of a voltage to the liquid crystal capacitor that is applied by causing the row driver to drive the switching circuit via the first wire and by supplying a data signal from the column driver via the fourth wire and the switching circuit to the first retaining section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a method of the present invention for driving a display device is a method for driving a display device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive,

the first retaining section including a liquid crystal capacitor whose pixel electrode is connected to a retaining node which retains the binary logic level of the first retaining section,

the first wire functioning also as a scanning signal line and the fourth wire functioning also as a data signal line,

the display device carrying out display by application of a voltage to the liquid crystal capacitor that is applied by causing the row driver to drive the switching circuit via the first wire and by supplying a data signal from the column driver via the fourth wire and the switching circuit to the first retaining section, and

a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, a leakage current can be reduced. This allows a reduction in power consumption.

In order to attain the above object, a method of the present invention for driving a display device is a method for driving a display device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section,

the first retaining section including a liquid crystal capacitor whose pixel electrode is connected to a retaining node which retains the binary logic level of the first retaining section,

the first wire functioning also as a scanning signal line and the fourth wire functioning also as a data signal line,

the display device carrying out display by application of a voltage to the liquid crystal capacitor that is applied by causing the row driver to drive the switching circuit via the first wire and by supplying a data signal from the column driver via the fourth wire and the switching circuit to the first retaining section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

In order to attain the above object, a method of the present invention for driving a display device a method for driving a display device including:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section;

a first voltage supply; and

a second voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first voltage supply supplying the first electric potential level to the first control section,

the second voltage supply supplying the second electric potential level to the first control section,

the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive,

the first retaining section including a liquid crystal capacitor whose pixel electrode is connected to a retaining node which retains the binary logic level of the first retaining section,

the first wire functioning also as a scanning signal line and the fourth wire functioning also as a data signal line,

the display device carrying out display by application of a voltage to the liquid crystal capacitor that is applied by causing the row driver to drive the switching circuit via the first wire and by supplying a data signal from the column driver via the fourth wire and the switching circuit to the first retaining section, and

a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

According to the invention, leakage into a retaining node which retains a binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

### Advantageous Effects of Invention

As described above, a memory device of the present invention includes:

a memory array in which memory cells are provided in a matrix pattern;

a row driver which drives each row of the memory array;

a column driver which drives each column of the memory array;

a first wire which is provided for the each row and which is connected to memory cells in an identical row;

a second wire and a third wire each of which is connected to the memory cells in the identical row;

and a fourth wire which is provided for the each column and which is connected to memory cells in an identical column, the fourth wire being driven by the column driver so that each of a first electric potential level and a second electric potential level each indicating a binary logic level is supplied to the fourth wire,

the memory cells of the memory array each including:

a switching circuit;

a first retaining section;

a transfer section;

a second retaining section;

a first control section; and

a voltage supply,

the switching circuit being driven by the row driver via the first wire, so as to select conduction/non-conduction between the fourth wire and the first retaining section,

the first retaining section retaining the binary logic level to be supplied thereto,

the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,

the second retaining section retaining the binary logic level to be supplied thereto,

the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,

the voltage supply supplying a set electric potential to the first control section, and

a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

### BRIEF DESCRIPTION OF DRAWINGS

FIG. 1, which shows an embodiment of the present invention, is a circuit diagram illustrating an arrangement of a memory circuit of Example 1.

FIG. 2 is a signal diagram illustrating an operation of the memory circuit of FIG. 1.

FIG. 3 is a circuit diagram showing leakage in a first state of the memory circuit of FIG. 1.

FIG. 4 is a circuit diagram showing leakage in a second state of the memory circuit of FIG. 1.

FIG. 5, which shows an embodiment of the present invention, is a circuit diagram illustrating an arrangement of a memory circuit of Example 2.

FIG. 6 is a signal diagram illustrating an operation of the memory circuit of FIG. 5.

FIG. 7 is a circuit diagram showing leakage in a first state of the memory circuit of FIG. 5.

FIG. 8 is a circuit diagram showing leakage in a second state of the memory circuit of FIG. 5.

FIG. 9, which shows an embodiment of the present invention, is a circuit diagram illustrating an arrangement of a memory circuit of Example 3.

FIG. 10 is a signal diagram illustrating an operation of the memory circuit of FIG. 9.

FIG. 11 is a circuit diagram showing leakage in a first state of the memory circuit of FIG. 9.

FIG. 12 is a circuit diagram showing leakage in a second state of the memory circuit of FIG. 9.

FIG. 13, which shows an embodiment of the present invention, is a circuit diagram illustrating an arrangement of a first memory circuit.

FIG. 14 is a signal diagram illustrating a writing operation of the memory circuit of FIG. 1.

FIG. 15 is a signal diagram illustrating another writing operation of the memory circuit of FIG. 1.

FIG. 16 is a signal diagram illustrating a reading operation of the memory circuit of FIG. 1.

FIG. 17, which shows an embodiment of the present invention, is a diagram explaining data polarities.

FIG. 18, which shows an embodiment of the present invention, is a circuit diagram illustrating an arrangement of a second memory circuit.

FIG. 19 is a signal diagram illustrating a writing operation of the memory circuit of FIG. 18.

FIG. 20, which shows an embodiment of the present invention, is a block diagram illustrating an arrangement of a memory device.

FIG. 21 is a block diagram illustrating how memory cells and wires of the memory device of FIG. 20 are arranged.

FIG. 22 is a block diagram illustrating an arrangement of the memory cell of FIG. 21.

FIG. 23 illustrates operations of the memory cell of FIG. 22. (a) through (h) of FIG. 23 illustrate the operations.

FIG. 24, which shows an embodiment of the present invention, is a block diagram illustrating an arrangement of a display device.

FIG. 25 is a circuit diagram illustrating an arrangement of a pixel in the display device of FIG. 24.

FIG. 26 is a signal diagram illustrating an operation of the pixel of FIG. 25.

FIG. 27, which shows a conventional art, is a circuit diagram illustrating an arrangement of a memory circuit.

FIG. 28 is a signal diagram illustrating a writing operation of the memory circuit of FIG. 27.

FIG. 29 is a circuit diagram illustrating electric potentials of nodes in the memory circuit of FIG. 27.

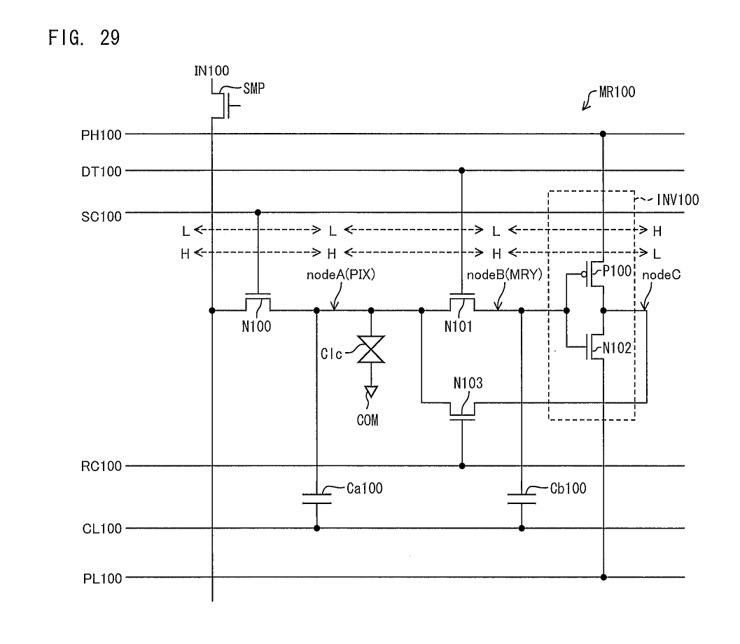

FIG. 30 is a signal diagram illustrating an operation of the memory circuit of FIG. 29.

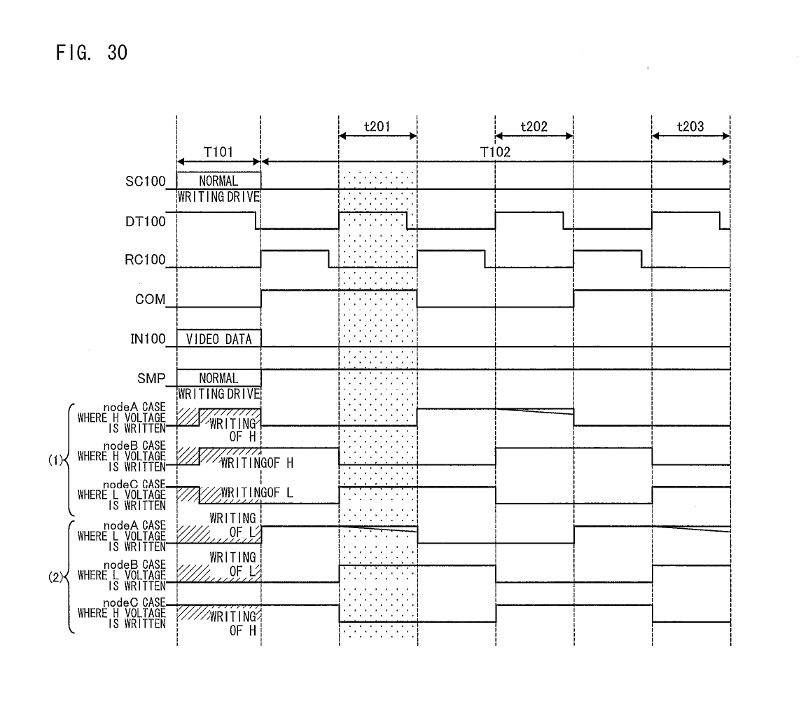

FIG. 31 is a circuit diagram explaining leakage in a first state of FIG. 30.

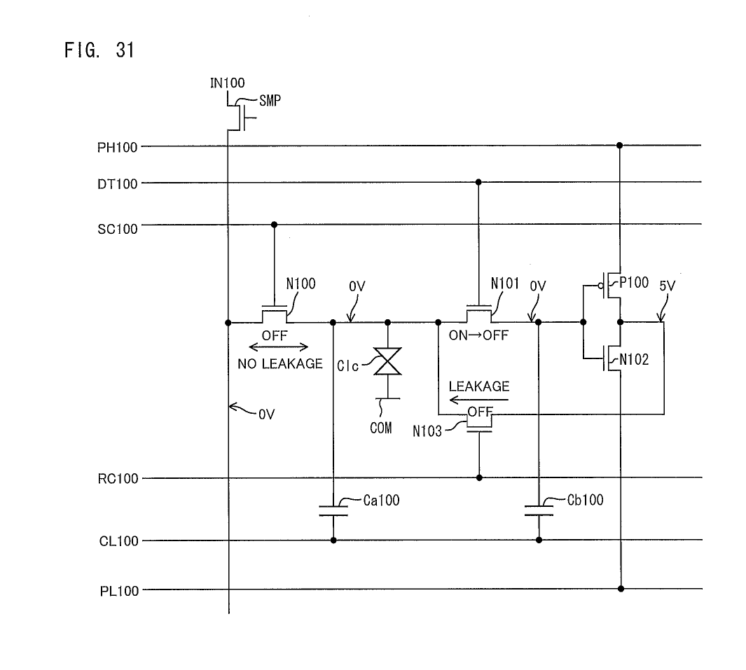

FIG. 32 is a circuit diagram explaining leakage in a second state of FIG. 30.

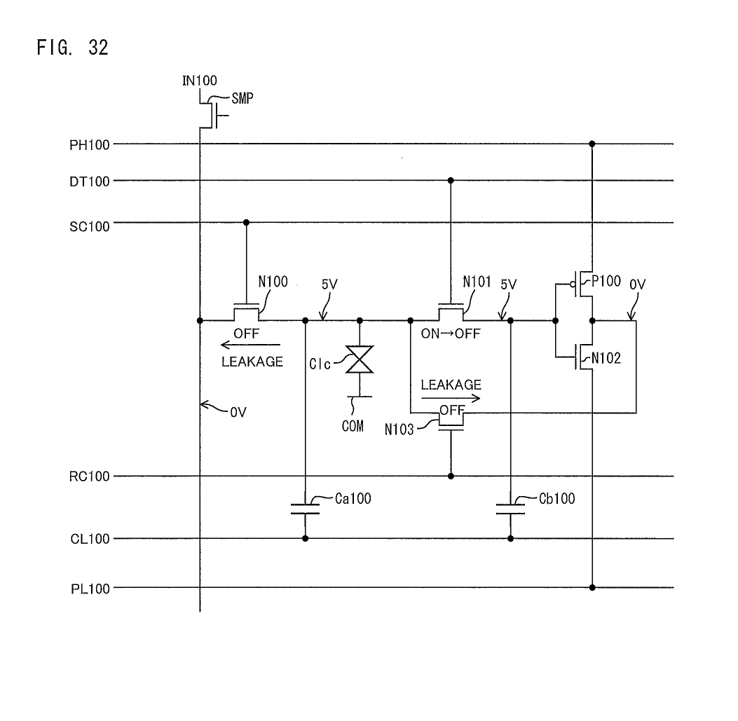

### DESCRIPTION OF EMBODIMENTS

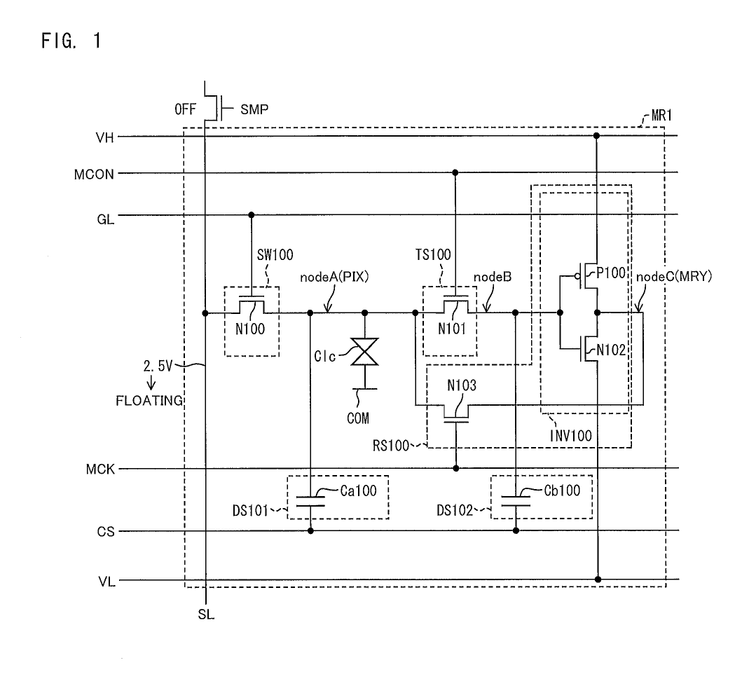

An embodiment of the present invention is described below with reference to FIG. 1 through FIG. 26.

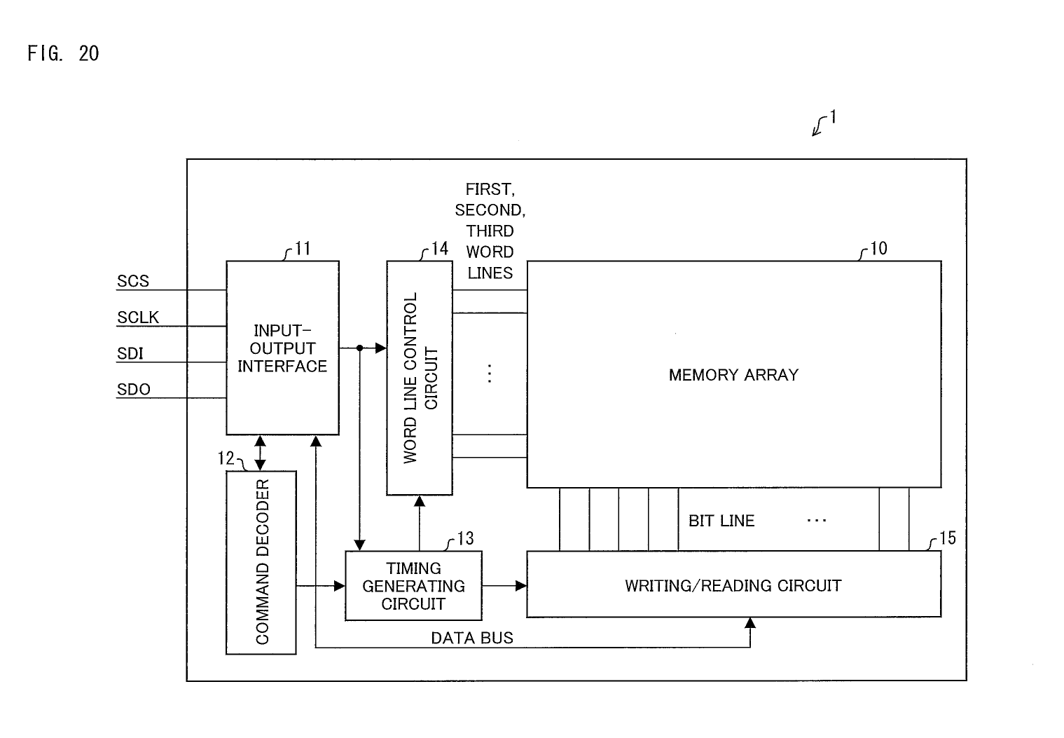

FIG. 20 illustrates an arrangement of a memory device 1 of the present embodiment.

The memory device 1 includes a memory array 10, an input-output interface 11, a command decoder 12, a timing generating circuit 13, a word line control circuit 14, and a writing/reading circuit 15.

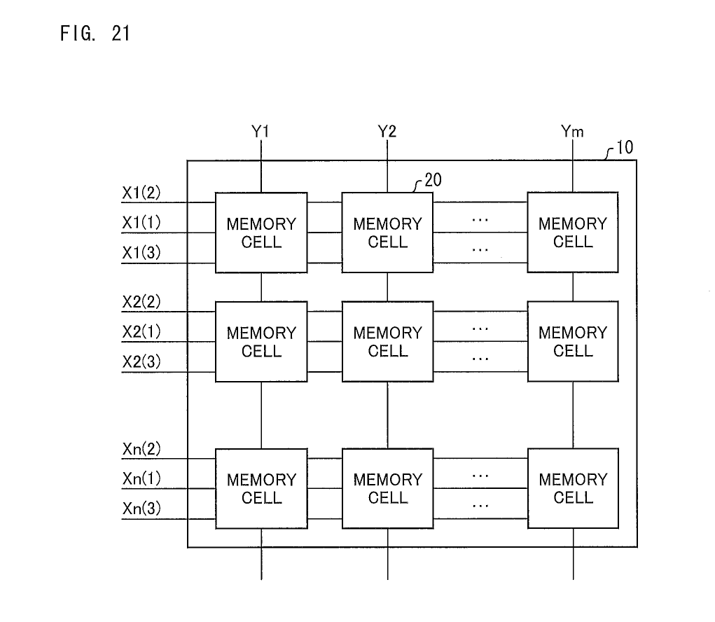

The memory array 10 is arranged such that memory cells 20 are provided in a matrix with n rows and m columns (see FIG. 21). Each of the memory cells 20 independently retains data. The first word line (first wire) Xi(1), the second word line (second wire) Xi(2), and the third word line (third wire) Xi(3) which are connected to the ith (i is an integer, 1≦i≦n) row, and a bit line (fourth wire) Yj which is connected to the jth (j is an integer, 1≦j≦m) column control writing and reading of data with respect to a memory cell 20 located at an intersection of the ith row and the jth column.

The input-output interface 11 controls an input-output of data between the memory device 1 and an outside of the memory device 1. For example, a four-wire serial interface used as the input-output interface 11 controls a transmission of a serial chip select signal SCS, a serial clock signal SCLK, a serial data input signal SDI, and a serial data output signal SDO (see FIG. 20). According to this, the input-output interface 11 receives a writing/reading command and/or an address/data from outside and supplies, to the outside, data read out from the memory array 10. The input-output interface 11 is not limited to the four-wire serial interface but may be a parallel interface.

The command decoder 12 is connected to each of the input-output interface 11 and the timing generating circuit 13. The command decoder 12 is a circuit which interprets the command received from the input-output interface 11 and selects an operation mode in accordance with the interpretation, so as to transmit the operation mode thus selected to the timing generating circuit 13.

The timing generating circuit 13 is connected to each of the input-output interface 11, the command decoder 12, the word line control circuit 14, and the writing/reading circuit 15. In accordance with the operation mode determined by the command decoder 12, the timing generating circuit 13 generates an internal timing signal which is necessary for each operation. A clock signal which serves as a basis for a timing may be supplied from an external system via the input-output interface 11 or may be generated inside the memory device 1 or inside the timing generating circuit 13 by an oscillator or the like.

The word line control circuit (row driver) 14 is connected to each of the memory array 10, the input-output interface 11, and the timing generating circuit 13. In accordance with the internal timing signal generated by the timing generating circuit 13, the word line control circuit 14 controls a word line which is appropriately selected, in accordance with a writing/reading address to be supplied from the input-output interface 11, from among a plurality of kinds of word lines of the first word line Xi(1), the second word line Xi(2), and the third word line Xi(3) (i is the row number) which are connected to each row of the memory array 10.

The writing/reading circuit (column driver) 15 is connected to each of the memory array 10, the input-output interface 11, and the timing generating circuit 13. In accordance with the internal timing signal generated by the timing generating circuit 13, the writing/reading circuit 15 controls the bit line Yj (j is the column number) which is connected to each column of the memory array 10. During writing of data, the writing/reading circuit 15 applies, to a bit line, a binary logic level in accordance with written data to be supplied from the input-output interface 11. During reading of data, the writing/reading circuit 15 senses an electric potential of each bit line and supplies data in accordance with a sensed value to the input-output interface 11. Binary logic levels are indicated by a first electric potential level and a second electric potential level. For example, one and the other of the first electric potential level and the second electric potential level are indicated by a High electric potential and a Low electric potential, respectively. The first electric potential level and the second electric potential level, which are logic levels, may have respective values falling within a given range.

Next, a specific arrangement of a memory cell 20 is described with reference to Examples.

### Example 1

FIG. 1 illustrates an arrangement of the memory cell 20 of the present Example in the form of the memory circuit MR1.

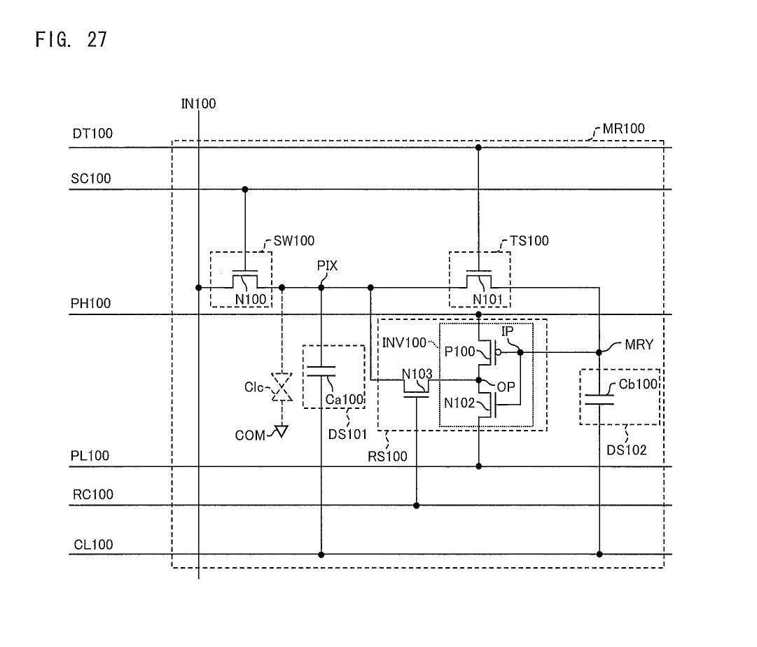

The memory circuit MR1 has an identical arrangement to the arrangement of FIG. 27.

Note, however, that a liquid crystal capacitor C1c is provided on the assumption that the memory circuit MR1 is used as a pixel of a display device as described later. Moreover, the data transfer control line DT100, the switch control line SC100, the High voltage supply line PH100, the Low voltage supply line PL100, the refresh output control line RC100, the capacitor wire CL100, and the data input line IN100 in FIG. 27 are illustrated as a control line MCON, a gate line GL, a voltage supply line VH, a voltage supply line VL, a control line MCK, a capacitor line CS, and a source line SL, respectively.

The gate line GL is a first word line Xi(1), the control line MCON is a second word line Xi(2), the control line MCK is a third word line Xi(3), and the source line SL is a bit line Yj.

The source line SL is connected to an output of the writing/reading circuit 15 via a sampling switch SMP.

The node PIX, the input terminal of the inverter

INV100, and the node MRY which is the output terminal of the inverter INV100 are referred to as a node A, a node B, and a node C, respectively.

The switching circuit (switching circuit) SW100 is driven by the row driver via the first wire, so as to select conduction/non-conduction between the fourth wire and the first retaining section.

The first data retaining section (first retaining section) DS101 retains the binary logic level supplied thereto.

The data transfer section (transfer section) TS100 is driven by the row driver via the second wire, so as to selectively carry out (i) a transfer operation in which the binary logic level retained in the first retaining section is transferred to the second retaining section while being retained in the first retaining section and (ii) a non-transfer operation in which no transfer operation is carried out.

The second data retaining section (second retaining section) DS102 retains the binary logic level supplied thereto.

The voltage supply line VH supplies High to the first control section.

The voltage supply line VL supplies Low to the first control section.

One and the other of the voltage supply line VH and the voltage supply line VL are a first voltage supply and a second voltage supply, respectively.

In the refresh output control section (first control section) RS100, an output element (transistor N103) of the first control section which is connected to the first retaining section is driven by the row driver via the third wire so as to be conductive or non-conductive an. The refresh output control section RS100 (i) transfers the second electric potential level (e.g., High) supplied from the second voltage supply (e.g., the voltage supply line VH) to the output element of the first control section via a connecting element (the inverter INV100), in a case where the binary logic level retained in the second retaining section is the first electric potential level (e.g., Low), and (ii) transfers the first electric potential level supplied from the first voltage supply (e.g., the voltage supply line VL) to the output element of the first control section via the connecting element, in a case where the binary logic level retained in the second retaining section is the second electric potential level.

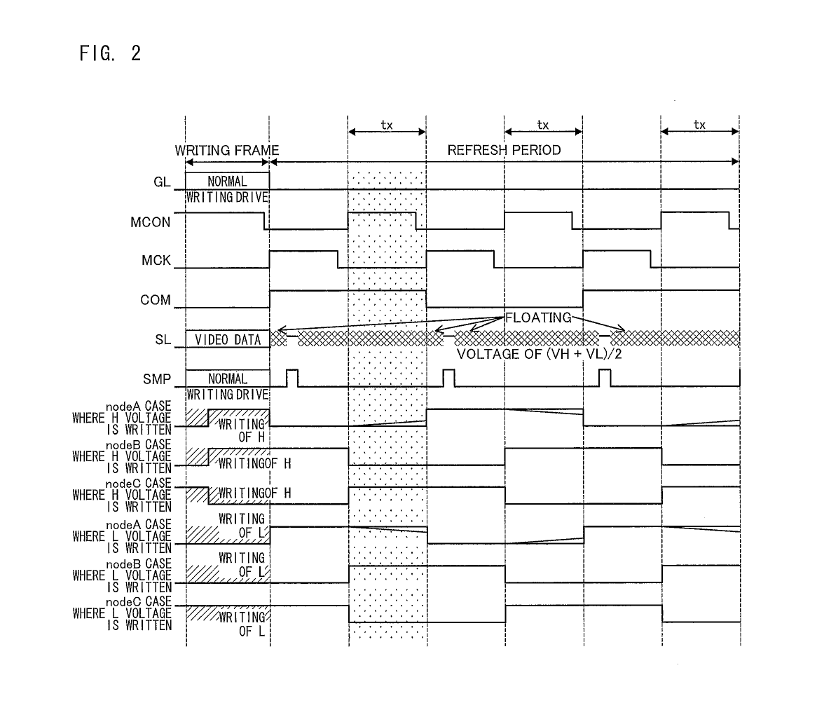

In the present Example, in an operation mode of supplying a binary logic level to the memory cell 20, the sections are driven as illustrated in FIG. 2. A writing frame and a refresh period are described later in detail. In the refresh period, inversion AC driving of the common electrode COM is carried out so that a polarity of a voltage applied to liquid crystals is reversed.

As illustrated in FIG. 2, in the refresh period, a predetermined period tx is set in which in a state where the first control section turns off the output element, (i) the first retaining section and the second retaining section retain an identical binary logic level, (ii) an electric potential between the first electric potential level and the second electric potential level (e.g., (VH+VL)/2 where VH is a High electric potential (5V) supplied from the voltage supply line VH and VL is a Low electric potential (0V) supplied from the voltage supply line VL) is supplied from the column driver to the fourth wire, and (iii) subsequently the fourth wire is shifted to a floating state.

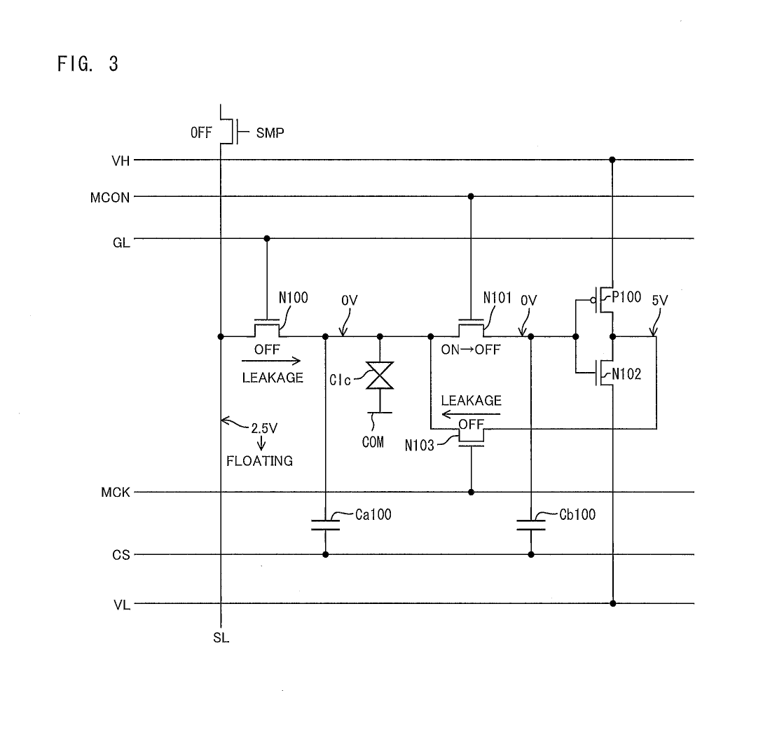

FIG. 3 illustrates a state in which leakage into the node A occurs in the predetermined period tx in a case where node A=0 V, node B=0 V, and node C=5 V and where 2.5 V is supplied to the source line SL and the source line SL is then shifted to a floating state. In the transistor N100, a leakage current from the source line SL towards the node A occurs. In the transistor N103, a leakage current from the node C towards the node A occurs.

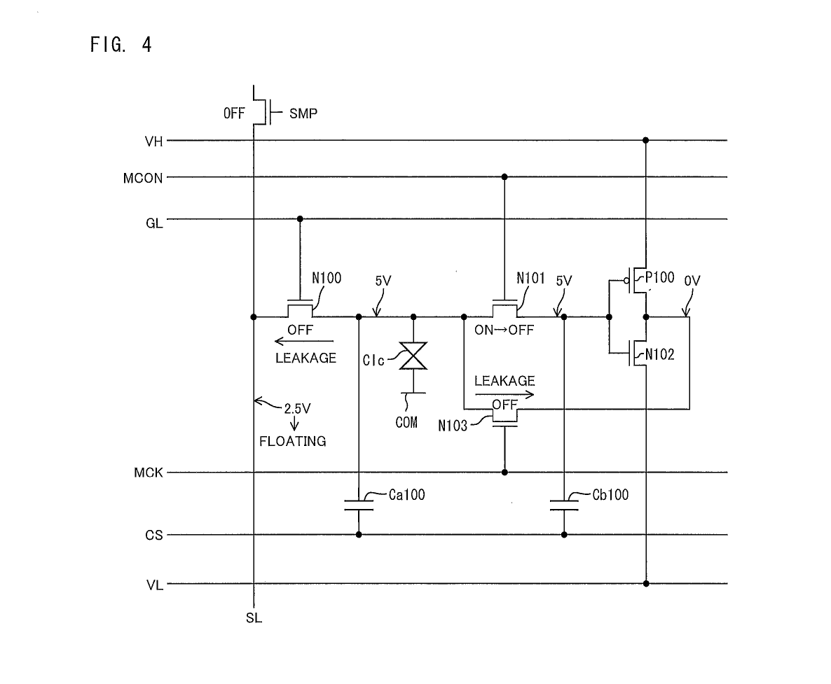

FIG. 4 illustrates a state in which leakage into the node A occurs in the predetermined period tx in a case where node A=5 V, node B=5 V, and node C=0 V and where 2.5 V is supplied to the source line SL and the source line SL is then shifted to a floating state. In the transistor N100, a leakage current from the node A towards the source line SL occurs. In the transistor N103, a leakage current from the node A towards the node C occurs.

According to the present Example, leakage into a retaining node which retains the binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, the leakage current can be reduced. This allows a reduction in power consumption.

### Example 2

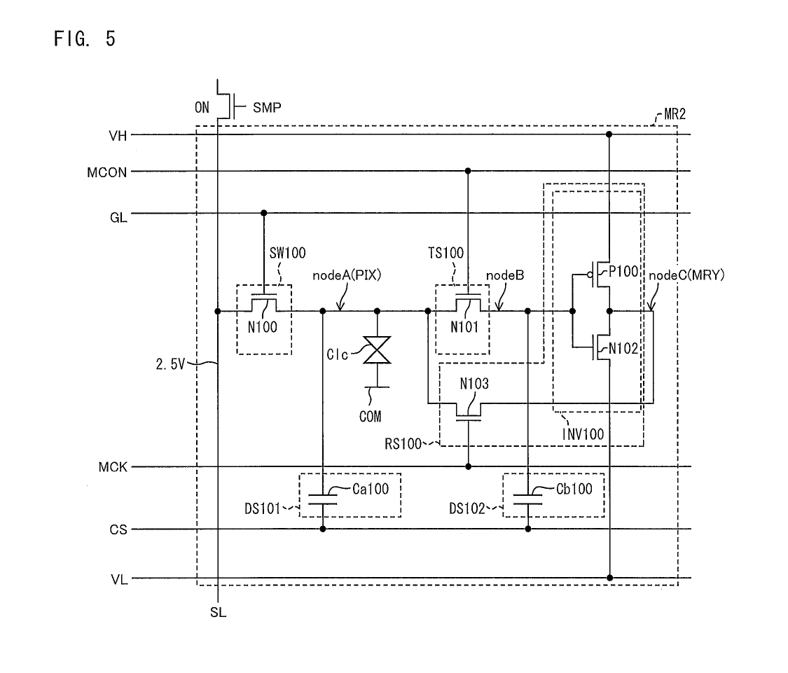

FIG. 5 illustrates an arrangement of a memory cell 20 of the present Example in the form of a memory circuit MR2.

The memory circuit MR2 has an identical arrangement to the memory circuit MR1.

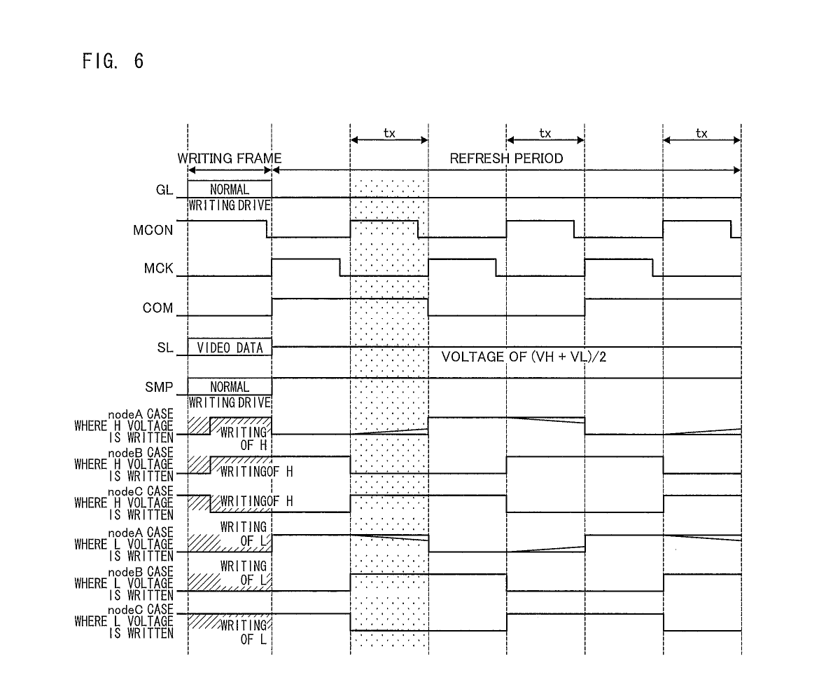

As illustrated in FIG. 6, in the refresh period, a predetermined period tx is set in which in a state where the first control section turns off the output element, (i) the first retaining section and the second retaining section retain an identical binary logic level, and (ii) an electric potential between the first electric potential level and the second electric potential level (e.g., (VH+VL)/2 where VH is a High electric potential (5V) supplied from the voltage supply line VH and VL is a Low electric potential (0V) supplied from the voltage supply line VL) continues to be supplied from the column driver to the fourth wire.

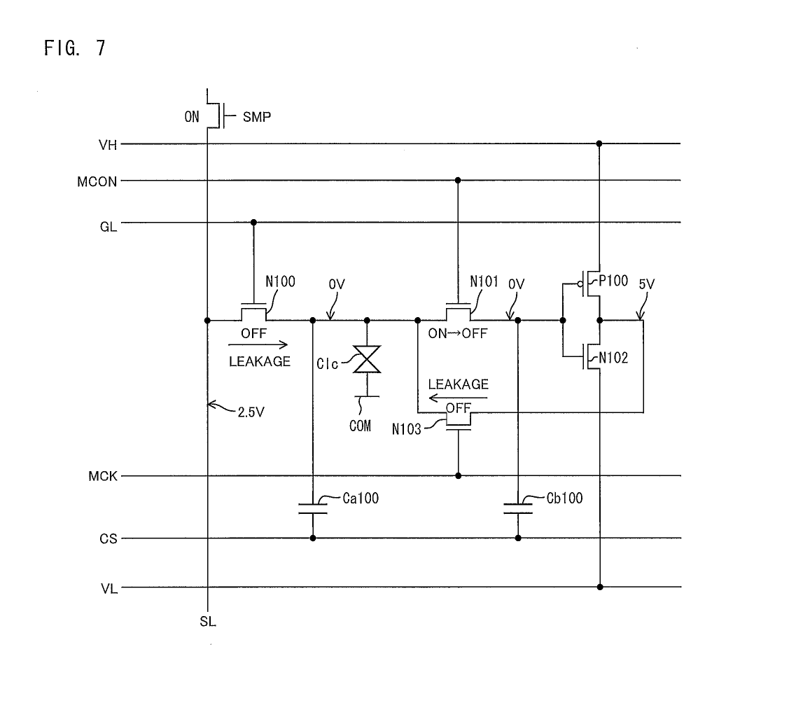

FIG. 7 illustrates a state in which leakage into the node A occurs in the predetermined period tx in a case where node A=0 V, node B=0 V, and node C=5 V and where 2.5 V continues to be supplied to the source line SL. In the transistor N100, a leakage current from the source line SL towards the node A occurs. In the transistor N103, a leakage current from the node C towards the node A occurs.

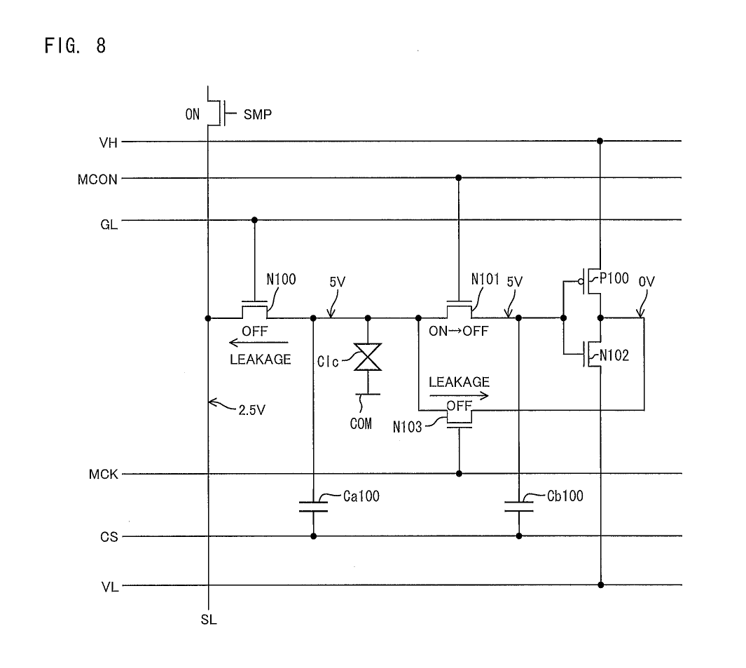

FIG. 8 illustrates a state in which leakage into the node A occurs in the predetermined period tx in a case where node A=5 V, node B=5 V, and node C=0 V and where the source line SL is set to 2.5 V and then 2.5 V continues to be supplied to the source line SL. In the transistor N100, a leakage current from the node A towards the source line SL occurs. In the transistor N103, a leakage current from the node A towards the node C occurs.

According to the present Example, leakage into a retaining node which retains the binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

### Example 3

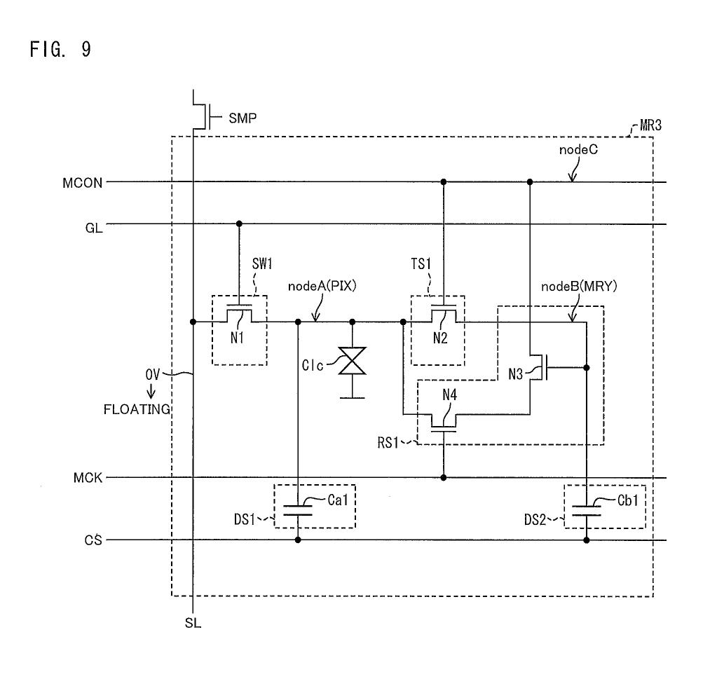

FIG. 9 illustrates an arrangement of a memory cell 20 of the present Example in the form of a memory circuit MR3.

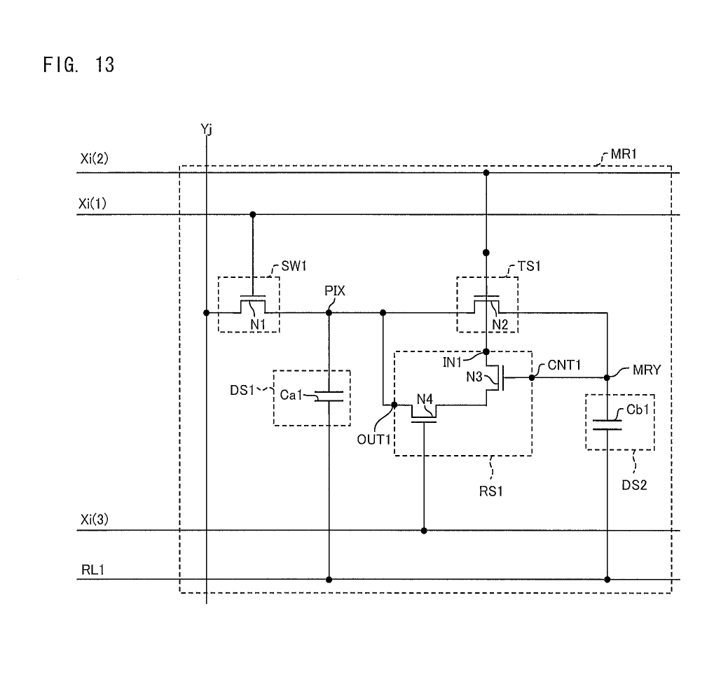

The memory circuit MR3 is identical to a memory circuit of FIG. 13 that is described later.

Note, however, that a liquid crystal capacitor C1c is provided on the assumption that the memory circuit MR3 is used as a pixel of a display device as described later. Moreover, the second word line Xi(2), the first word line Xi(1), the third word line Xi(3), the reference electric potential wire RL1, and the bit line Yj in FIG. 13 are illustrated as a control line MCON, a gate line GL, a control line MCK, a capacitor line CS, and a source line SL, respectively.

The source line SL is connected to an output of the writing/reading circuit 15 via a sampling switch SMP.

The node PIX, the node MRY, and the control line MCON in FIG. 13 are referred to as a node A, a node B, and a node C, respectively.

The switching circuit (switching circuit) SW1 is driven by the row driver via the first wire, so as to select conduction/non-conduction between the fourth wire and the first retaining section.

The first data retaining section (first retaining section) DS1 retains the binary logic level supplied thereto.

The data transfer section (transfer section) TS1 is driven by the row driver via the second wire, so as to selectively carry out (i) a transfer operation in which the binary logic level retained in the first retaining section is transferred to the second retaining section while being retained in the first retaining section and (ii) a non-transfer operation in which no transfer operation is carried out.

The second data retaining section (second retaining section) DS2 retains the binary logic level supplied thereto.

In the refresh output control section (first control section) RS1, an output element (transistor N4) of the first control section which is connected to the first retaining section is driven by the row driver via the third wire so as to conductive or non-conductive. The refresh output control section RS1 determines, in accordance with the binary logic level retained in the second retaining section, whether or not an electric potential supplied from a voltage supply is transferred to the output element of the first control section via the connecting element (transistor N3).

The control line (voltage supply) MCON supplies a set electric potential to the first control section.

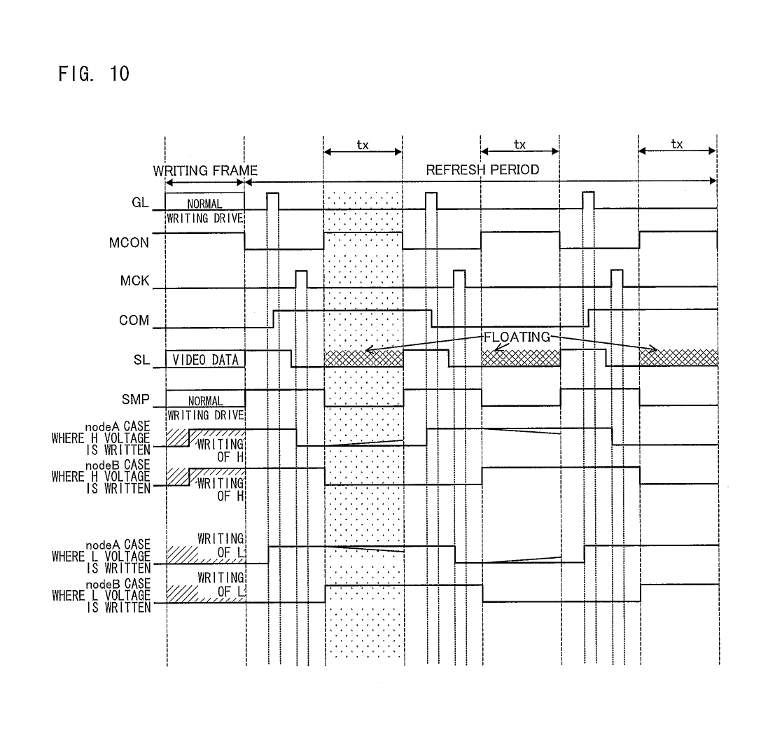

As illustrated in FIG. 10, in the refresh period, a predetermined period tx is set in which in a state where the first control section turns off the output element, (i) the first retaining section and the second retaining section retain an identical binary logic level, (ii) the electric potential of the voltage supply is set to one of the first electric potential level and the second electric potential level (High in FIG. 10 for example), (iii) the other one of the first electric potential level and the second electric potential level (Low in FIG. 10 for example) is supplied from the column driver to the fourth wire, and (iv) subsequently the fourth wire is shifted to a floating state.

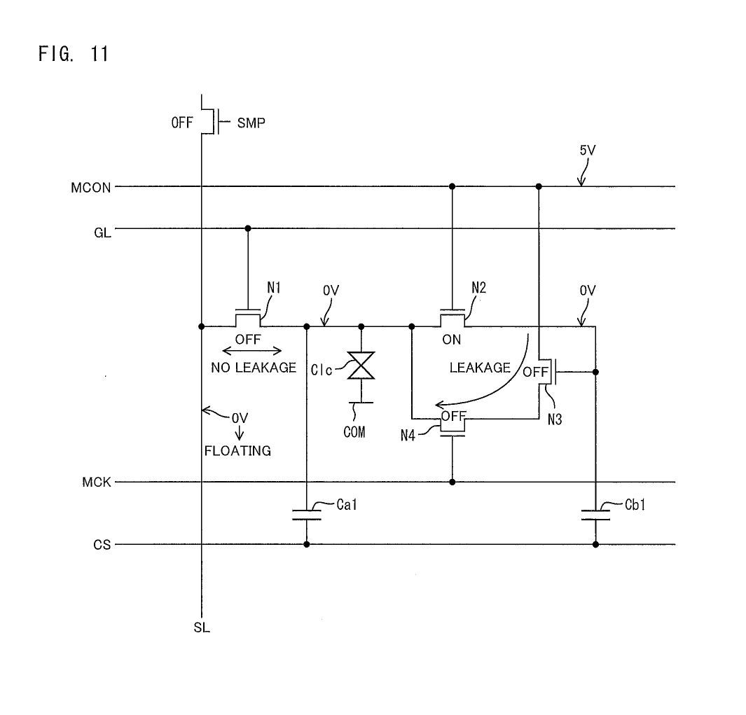

FIG. 11 illustrates a state where leakage into the node A occurs in the predetermined period tx in a case where node A=0 V, node B=0 V, and node C=5 V and where 0 V is supplied to the source line SL and the source line SL is then shifted to a floating state. In the transistor N1, no leakage current occurs. In the transistors N3 and N4, a leakage current from the node C towards the node A occurs.

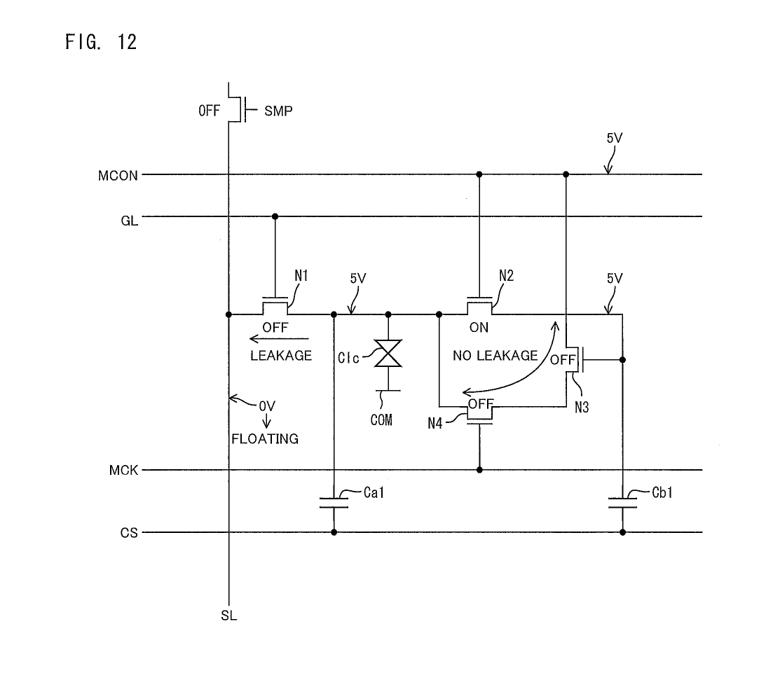

FIG. 12 illustrates a state in which leakage into the node A occurs in the predetermined period tx in a case where node A=5 V, node B=5 V, and node C=5 V and where 0 V is supplied to the source line SL and the source line SL is then shifted to a floating state. In the transistor N1, a leakage current from the node A towards the source line SL occurs. In the transistors N3 and N4, no leakage current occurs.

According to the present Example, leakage into a retaining node which retains the binary logic level of the first retaining section is balanced between a case where the retaining node retains the first electric potential level and a case where the retaining node retains the second electric potential level.

It is thus possible to provide a memory device which includes two retaining sections in which a binary logic level corresponding to written data is retained, a transfer section for transferring the binary logic level between the two retaining sections, and a circuit for carrying out a refresh operation of one retaining section on the basis of a binary logic level retained in the other retaining section, wherein an amount of leakage into a first retaining section to which a binary logic level is written from a wire for supplying the binary logic level to a memory cell can be balanced between different circuit states.

Moreover, since the fourth wire is in a floating state, the leakage current can be reduced. This allows a reduction in power consumption.

It is also possible that in the predetermined period tx, in a state where the first control section turns off the output element, (i) the first retaining section and the second retaining section retain an identical binary logic level, (ii) the electric potential of the voltage supply is set to one of the first electric potential level and the second electric potential level (High in FIG. 10 for example), and (iii) the other one of the first electric potential level and the second electric potential level (Low in FIG. 10 for example) continues to be supplied from the column driver to the fourth wire.

Next, the following describes in detail the memory cell 20 used in Example 3

[Detailed Description of Memory Cell 20 Used in Example 3]

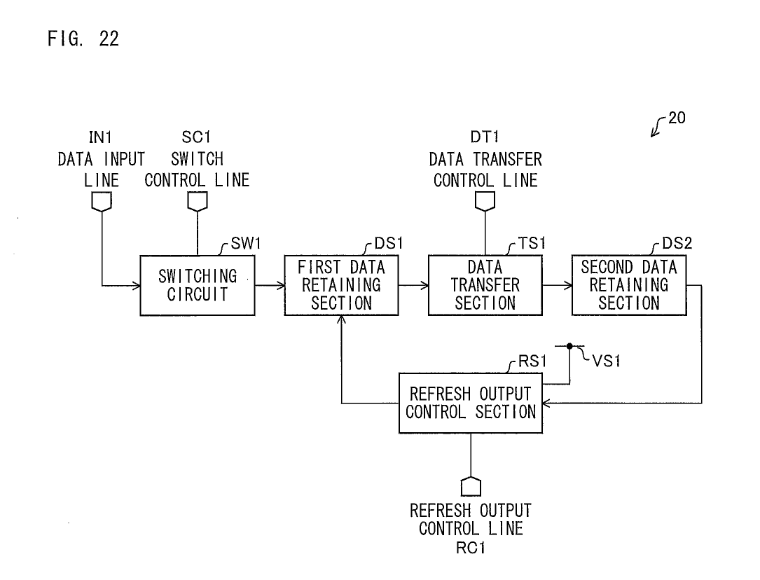

FIG. 22 shows a concept of an arrangement of each memory cell 20.

A memory cell 20 includes a switching circuit SW1, a first data retaining section DS1, a data transfer section TS1, a second data retaining section DS2, a refresh output control section RS1, and a voltage supply VS1.

The memory array 10 includes a data input line IN1, a switch control line SC1, a data transfer control line DT1, and a refresh output control line RC1. In FIG. 21, the bit line Yj corresponds to the data input line IN1, the first word line Xi(1) corresponds to the switch control line SC1, the second word line Xi(2) corresponds to the data transfer control line DT1, and the third word line Xi(3) corresponds to the refresh output control line RC1.

The switching circuit SW1 is driven by the word line control circuit 14 via the switch control line SC1 (first wire), so as to select conduction/non-conduction between the data input line (fourth wire) IN1 and the first data retaining section (first retaining section) DS1.

The first data retaining section DS1 retains a binary logic level to be supplied thereto.

The data transfer section (transfer section) TS1 is driven by the word line control circuit 14 via the data transfer control line (second wire) DT1, so as to selectively carry out (i) a transfer operation in which the binary logic level retained in the first data retaining section DS1 is transferred to the second data retaining section DS2 while being retained in the first data retaining section DS1 and (ii) a non-transfer operation in which no transfer operation is carried out. Note that, since a signal to be supplied to the data transfer control line DT1 is shared by all the memory cells 20, the data transfer control line DT1 is not necessarily required to be provided for each row to be driven by the word line control circuit 14. The data transfer control line DT1 may be driven by the writing/reading circuit 15 or the like.

The second data retaining section (second retaining section) DS2 retains the binary logic level to be supplied thereto.

The refresh output control section (first control section) RS1 is driven by the word line control circuit 14 via the refresh output control line (third wire) RC1, so as to be selectively controlled to be in a state in which the refresh output control section RS1 carries out a first operation or a second operation. Note that, since a signal to be supplied to the refresh output control line RC1 is shared by all the memory cells 20, the refresh output control line RC1 is not necessarily required to be provided for each row to be driven by the word line control circuit 14. The refresh output control line RC1 may be driven by the writing/reading circuit 15 or the like.

In the first operation, an active state or a non-active state is selected in accordance with control information indicative of which of the first electric potential level and the second electric potential level is retained in the second data retaining section DS2 as the binary logic level. In the active state, the refresh output control section RS1 receives an input thereto and supplies the input as an output thereof to the first data retaining section DS1. In the non-active state, the refresh output control section RS1 stops carrying out an output.

In the second operation, the refresh output control section RS1 stops carrying out the output regardless of the control information.

The voltage supply VS1 supplies a set electric potential to an input of the refresh output control section RS1.

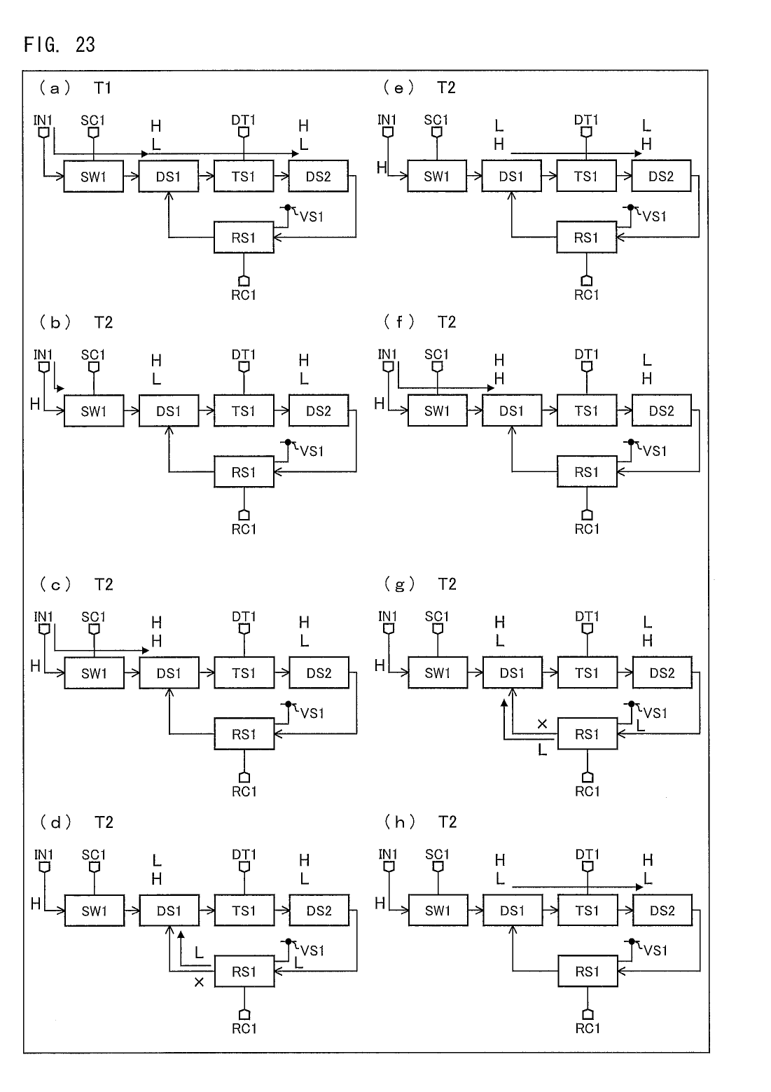

Next, a transition of a state of the memory cell 20 is described below with reference to (a) through (h) of FIG. 23. Each of (a) through (h) of FIG. 23 illustrates “H” assuming that the first electric potential level is High and illustrates “L” assuming that the second electric potential level is Low. As for parts of FIG. 23 in each of which “H” and “L” are vertically juxtaposed to each other, the upper “H” or “L” shows a transition state of an electric potential level obtained during writing of “H” to the memory cell 20, and the lower “H” or “L” shows a transition state of an electric potential level obtained during writing of “L” to the memory cell 20.

First, a writing period T1 for writing data is set in a data writing mode.

In the writing period T1, the switch control line SC1 causes the switching circuit SW1 to turn on, and a binary logic level to be retained is supplied from the data input line IN1 via the switching circuit SW1 to the first data retaining section DS1, the binary logic level being indicated by the first electric potential level or the second electric potential level corresponding to data (see (a) of FIG. 23).

In response to the supply of the binary logic level to the first data retaining section DS1, the switch control line SC1 causes the switching circuit SW1 to turn off. In this case, the data transfer control line DT1 causes the data transfer section TS1 to turn on, i.e., to be in a state in which the data transfer section TS1 carries out the transfer operation, and the binary logic level having been supplied to the first data retaining section DS1 is transferred from the first data retaining section DS1 via the data transfer section TS1 to the second data retaining section DS2 while being retained in the first data retaining section DS1. In a case where the binary logic level has been transferred to the second data retaining section DS2, the data transfer section TS1 turns off, i.e., is in a state in which the data transfer section TS1 carries out the non-transfer operation.

A refresh period T2 is set following the writing period T1.

In the refresh period T2, the first electric potential level is first supplied from the writing/reading circuit 15 to the data input line IN1 (see (b) of FIG. 23).

Then, the switch control line SC1 causes the switching circuit SW1 to turn on, and the first electric potential level is supplied from the data input line IN1 via the switching circuit SW1 to the first data retaining section DS1 (see (c) of FIG. 23). In response to the supply of the first electric potential level to the first data retaining section DS1, the switch control line SC1 causes the switching circuit SW1 to turn off.

Next, the refresh output control line RC1 controls the refresh output control section RS1 to be in a state in which the refresh output control section RS1 carries out the first operation (see (d) of FIG. 23). The refresh output control section RS1 carries out the first operation differently in accordance with the control information indicative of which of the first electric potential level and the second electric potential level is retained in the second data retaining section DS2 as the binary logic level.

Namely, in a case where the first electric potential level is retained in the second data retaining section DS2 and first control information indicating that the first electric potential level is retained in the second data retaining section DS2 is transmitted from the second data retaining section DS2 to the refresh output control section RS1, the refresh output control section RS1 is in the active state, in which the refresh output control section RS1 receives the input thereto and supplies the input as the output thereof to the first data retaining section DS1. In a case where the refresh output control section RS1 carries out the first operation, the electric potential of the voltage supply VS1 is set so that the second electric potential level can be at least finally supplied to the input of the refresh output control section RS1 in a period during which the first control information is being transmitted to the refresh output control section RS1. In this case, the first data retaining section DS1 retains the second electric potential level in a state in which the binary logic level having been retained therein until then is overwritten with the second electric potential level having been supplied from the refresh output control section RS1.

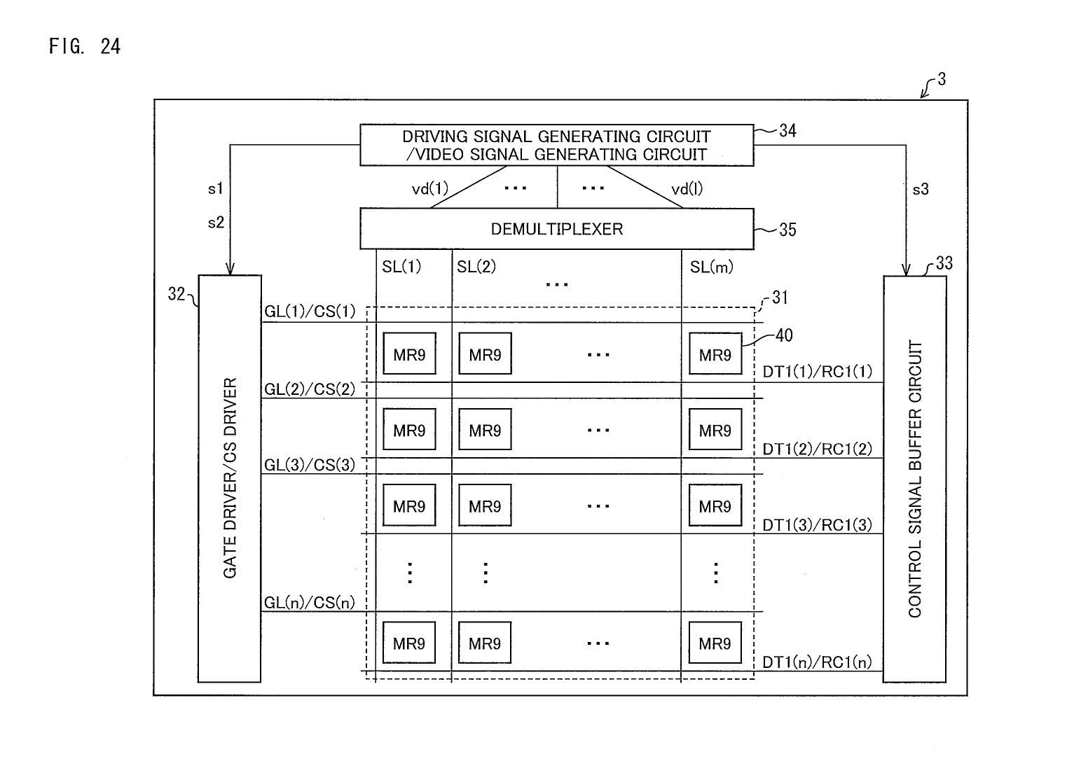

In contrast, in a case where the second electric potential level is retained in the second data retaining section DS2, the refresh output control section RS1 is in the non-active state. In a case where second control information indicating that the second electric potential level is retained in the second data retaining section DS2 is transmitted from the second data retaining section DS2 to the refresh output control section RS1, the refresh output control section RS1 is in a state in which the refresh output control section RS1 stops carrying out the output (an “X” in FIG. 24). In this case, the first data retaining section DS1 continues retaining the first electric potential level having been retained therein until then.

Thereafter, the refresh output control line RC1 controls the refresh output control section RS1 to be in a state in which the refresh output control section RS1 carries out the second operation.

Subsequently, in the refresh period T2, the data transfer control line DT1 causes the data transfer section TS1 to be in the state in which the data transfer section TS1 carries out the transfer operation, and binary logic data having been retained in the first data retaining section DS1 until then is transferred from the first data retaining section DS1 via the data transfer section TS1 to the second data retaining section DS2 while being retained in the first data retaining section DS1 (see (e) of FIG. 23). In a case where the binary logic data has been transferred from the first data retaining section DS1 to the second data retaining section DS2, the data transfer section TS1 turns off, i.e., is in a state in which the data transfer section TS1 carries out the non-transfer operation.

Then, the switch control line SC1 causes the switching circuit SW1 to turn on, and the first electric potential level is supplied from the data input line IN1 via the switching circuit SW1 to the first data retaining section DS1 (see (f) of FIG. 23). In response to the supply of the first electric potential level to the first data retaining section DS1, the switch control line SC1 causes the switching circuit SW1 to turn off.

Next, the refresh output control line RC1 controls the refresh output control section RS1 to be in a state in which the refresh output control section RS1 carries out the first operation (see (g) of FIG. 23). In a case where the first electric potential level is retained in the second data retaining section DS2, the refresh output control section RS1 is in the active state, in which the refresh output control section RS1 supplies, to the first data retaining section DS1, the second electric potential level to be supplied from the voltage supply VS1. In this case, the first data retaining section DS1 retains the second electric potential level in a state in which the binary logic level having been retained therein until then is overwritten with the second electric potential level having been supplied from the refresh output control section RS1. In contrast, in a case where the second electric potential level is retained in the second data retaining section DS2, the refresh output control section RS1 is in the non-active state, in which the refresh output control section RS1 stops carrying out the output. In this case, the first data retaining section DS1 continues retaining the first electric potential level having been retained therein until then. Thereafter, the refresh output control line RC1 controls the refresh output control section RS1 to be in a state in which the refresh output control section RS1 carries out the second operation, so that the refresh output control section RS1 is in a state in which the refresh output control section RS1 stops carrying out the output.

Subsequently, the data transfer control line DT1 causes the data transfer section TS1 to be in the state in which the data transfer section TS1 carries out the transfer operation, and the binary logic level having been retained in the first data retaining section DS1 until then is transferred from the first data retaining section DS1 via the data transfer section TS1 to the second data retaining section DS2 while being retained in the first data retaining section DS1 (see (h) of FIG. 23). In a case where the binary logic level has been transferred from the first data retaining section DS1 to the second data retaining section DS2, the data transfer section TS1 turns off, i.e., is in a state in which the data transfer section TS1 carries out the non-transfer operation.

In (h) of FIG. 23, the above series of operations allows the binary logic level having been written in the writing period T1 of (a) of FIG. 23 to be restored in each of the first data retaining section DS1 and the second data retaining section DS2. Accordingly, data having been written in the writing period T1 is similarly restored even if the operations from (b) to (h) of FIG. 23 are repeated any number of times after the operation (h) of FIG. 23.

Note here that, in a case where the first electric potential level (High here) has been written in the writing period T1, the binary logic level is refreshed by being subjected to a level reversal carried out one time in each of (d) of FIG. 23 and (f) of FIG. 23, so that the binary logic level thus refreshed is restored to the first electric potential level. In a case where the second electric potential level (Low here) has been written in the writing period T1, the binary logic level is refreshed by being subjected to a level reversal carried out one time in each of (c) of FIG. 23 and (g) of FIG. 23, so that the binary logic level thus refreshed is restored to the second electric potential level.

Note that, in a case where the first electric potential level is Low and the second electric potential is High, it is only necessary that the above operation logic be reversed.

In the refresh period T2, the first electric potential level is supplied from the data input line IN1 to the first data retaining section DS1 (see (c) and (f) of FIG. 23), and the refresh output control section RS1 supplies the second electric potential level from the voltage supply VS1 to the first data retaining section DS1 (see (d) and (g) of FIG. 23). Therefore, unlike a conventional art, it is unnecessary to provide an inverter so as to carry out a refresh operation.

As described earlier, according to the memory device 1, in a case where one and the other of the first electric potential level and the second electric potential level are supplied from the data input line IN1 and the voltage supply VS1, respectively to each of the memory cells 20 by no use of an inverter after binary logic data has been written to the first data retaining section DS1, a binary logic level corresponding to the binary logic data having been written to a memory cell 20 can be refreshed while being subjected to a level reversal. Since a binary logic level which has been refreshed and is retained in the first data retaining section DS1 and a binary logic level which has been refreshed and is retained in the second data retaining section DS2 are equal to each other, the first data retaining section DS1 and the second data retaining section DS2 do not change in electric potential even if the data transfer section TS1 carries out the transfer operation. This allows both the first data retaining section DS1 and the second data retaining section DS2 to retain the binary logic levels thus refreshed for a long time while the data transfer section TS1 is in a state in which the data transfer section TS1 carries out the transfer operation. In this case, since the first data retaining section DS1 and the second data retaining section DS2 are connected via the data transfer section TS1, occurrence of an off-leakage current in a transfer element of the data transfer section TS1 is irrelevant to retention of the binary logic levels. The binary logic levels, which are retained in a mass by a large electric capacitance represented by a sum of the first data retaining section DS1 and the second data retaining section DS2, are less likely to change in electric potential even by an influence of a noise from outside.

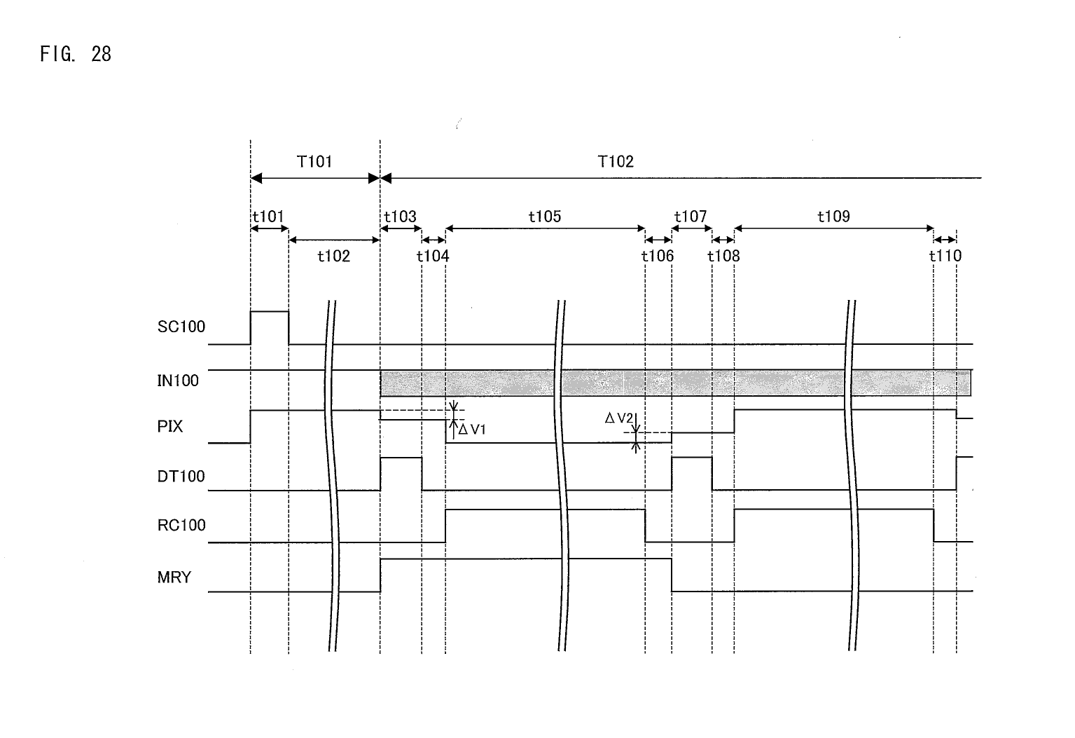

Accordingly, even if the off-leakage current occurs in the transfer element used in the data transfer section TS1, an electric potential of a retaining node which retains the binary logic level of the second data retaining section DS2 is less likely to change since the electric potential is retained for a long time together with an electric potential of a retaining node of the first data retaining section DS1. According to a conventional memory cell, the binary logic levels which have been refreshed and are different from each other are retained for a long time in a state in which the first data retaining section DS1 and the second data retaining section DS2 are electrically separated from each other by the transfer element (transistor N101) of the data transfer section TS100 (see the period t105 and the period t109 which are illustrated in FIG. 28). Therefore, the off-leakage current of the transfer element has a great influence on the electric potential of the second data retaining section DS102.

Further, even if the electric potential of the retaining node of the second data retaining section DS2 changes, a time for the change is not long enough for the control information for the refresh control section RS1 carrying out the first operation to change between the active level and the non-active level.

In a case where it is assumed that an inverter exists in the refresh control section RS1, there exist two complementary levels of a High level and a Low level as active levels at each of which the inverter operates. Therefore, a range is narrow in which the electric potential of the second data retaining section DS2 can exist as a level at which the inverter stably maintains an identical operation. For example, assume that the electric potential of the second data retaining section DS2 is at the Low level. While the inverter is being operated so that a p-channel transistor turns on and an n-channel transistor turns off, it is feared that a slight increase in gate electric potential of the p-channel transistor may cause the n-channel transistor to turn on. However, in a case where the n-channel transistor is designed to have a large threshold voltage so as to avoid such a fear and the inverter is desired to operate so that the p-channel transistor turns off and the n-channel transistor turns on, a range becomes narrow in which the High level functions as the active level. In contrast, according to the present embodiment, the active level of the refresh control section RS1 is one of the first electric potential level and the second electric potential level. Therefore, in a case where a broad range is secured in which the control information for the refresh control section RS1 exists as the non-active level, it is less feared that the non-active level may change to the active level. In contrast, in a case where the active level functions at an early stage of the active state of the first operation of the refresh control section RS1, an object of the active level to be supplied from the voltage supply section VS1 to the first data retaining section DS1 is easily attained. Therefore, even in a case where the active level finally changes to the non-active level, the change is less likely to cause an operation error in the refresh control section RS1. Accordingly, even if the electric potential of the retaining node of the second data retaining section DS2 changes, it is possible to carry out designing with such a large margin as to prevent the operation error in the refresh control section RS1. For example, assume that the control information for the refresh control section RS1 is supplied to a gate of a transistor. Such designing corresponds to designing such that an increase in threshold voltage of the transistor causes a gate-source voltage to be less likely to exceed the threshold voltage of the transistor even if the electric potential of the second data retaining section DS2 which electric potential should be at the non-active level changes.

Further, in a case where the electric potential of the retaining node of the second data retaining section DS2 changes but the refresh output control section RS1 carries out the second operation, no operation error occurs.

Accordingly, it is possible to provide a memory device such that, even if an off-leakage current occurs in a transfer element used in a transfer section which transfers binary logic data between two retaining sections, a circuit which carries out a refresh operation in accordance with a binary logic level retained in one of the two retaining sections can suitably carry out its original operation with no increase in consumption current and no operation error.

Next, the following description specifically discusses an arrangement and an operation of the memory cell 20.

FIG. 13 illustrates an arrangement of the memory cell 20 of the present Example in the form of a memory circuit MR1 which is an equivalent circuit.

As described above, the memory circuit MR1 includes a switching circuit SW1, a first data retaining section DS1, a data transfer section TS1, a second data retaining section DS2, and a refresh output control section RS1.

The switching circuit SW1 includes a transistor N1 which is an N-channel TFT. The first data retaining section DS1 includes a capacitor (first capacitor) Ca1. The data transfer section TS1 includes a transistor (third switch) N2 which is an N-channel TFT serving as a transfer element. The second data retaining section DS2 includes a capacitor (second capacitor) Cb1. The refresh output control section RS1 includes a transistor (first switch) N3 which is an N-channel TFT and a transistor (second switch) N4 which is an N-channel TFT. The capacitor Ca1 is larger than the capacitor Cb1 in capacitance value.

That is, in FIG. 13, all the transistors constituting the memory circuit are N-channel TFTs (field-effect transistors). Accordingly, the memory circuit MR1 can be easily built into amorphous silicon.

As wires for driving each memory circuit MR1, the memory device 1 includes a reference electric potential wire RL1 in addition to the first word line Xi(1), the second word line Xi(2), the third word line Xi(3), and the bit line Yj.

One and the other of drain/source terminals of a field-effect transistor such as a TFT mentioned above are hereinafter referred to as a first drain/source terminal and a second drain/source terminal, respectively. The same applies to the other Examples.

The transistor N1 has a gate terminal which is connected to the first word line Xi(1), a first drain/source terminal which is connected to the bit line Yj, and a second drain/source terminal which is connected to a node (retention node) PIX which is one end of the capacitor Ca1. The other end of the capacitor Ca1 is connected to the reference electric potential wire RL1. In a state in which the transistor N1 is on, the switching circuit SW1 is in a conductive state. Meanwhile, in a case where the transistor N1 is off, the switching circuit SW1 is in a non-conductive state.

The transistor N2 has a gate terminal which is connected to the second word line Xi(2), a first drain/source terminal which is connected to the node PIX, and a second drain/source terminal which is connected to a node (retention node) MRY which is one end of the capacitor Cb1. The other end of the capacitor Cb1 is connected to the reference electric potential wire RL1. In a state in which the transistor N2 is on, the data transfer section TS1 is in a state in which the data transfer section TS1 carries out the transfer operation. Meanwhile, in a state in which the transistor N2 is off, the data transfer section TS1 is in a state in which the data transfer section TS1 carries out the non-transfer operation.

The transistor N3 has a gate terminal which is connected, as a control terminal CNT1 of the refresh output control section RS1, to the node MRY, a first drain/source terminal which is connected, as an input terminal IN1 of the refresh output control section RS1, to the second word line Xi(2), and a second drain/source terminal which is connected to a first drain/source terminal of the transistor N4. The transistor N4 has a gate terminal which is connected to the third word line Xi(3), and a second drain/source terminal which is connected, as an output terminal OUT1 of the refresh output control section RS1, to the node PIX. That is, the transistor N3 and the transistor N4 are serially connected to each other between an input of the refresh output control section RS1 and an output of the refresh output control section RS1 so that the transistor N3 is located on the input side of the refresh output control section RS1. Note that the position of the transistor N3 and the position of the transistor N4 in the above example may be exchanged with each other. Namely, it is only necessary that the transistor N3 and the transistor N4 be serially connected to each other between the input of the refresh output control section RS1 and the output of the refresh output control section RS1.

In a state in which the transistor N4 is on, the refresh output control section RS1 is controlled to be a state in which the refresh output control section RS1 carries out the first operation. Meanwhile, in a state in which the transistor N4 is off, the refresh output control section RS1 is controlled to be a state in which the refresh output control section RS1 carries out the second operation. Since the transistor N3 is an N-channel TFT, control information which causes the refresh output control section RS1 to be in an active state during the first operation, i.e., an active level is High, and control information which causes the refresh output control section RS1 to be in a non-active state during the first operation, i.e., a non-active level is Low.

The following describes operation of the memory circuit MR1 arranged as above.

First, writing operation of the memory circuit MR1 is described.

The writing operation is carried out as follows. Specifically, the input-output interface 11 receives a writing command and a writing address from an outside of the memory device 1 via a transmission line, and the command decoder 12 interprets the command and shifts into a writing mode. In accordance with a signal indicative of the writing mode of the command decoder 12, the timing generating circuit 13 generates an internal timing signal for the writing operation. The word line control circuit 14 controls a first word line Xi(1), a second word line Xi(2), and a third word line Xi(3) that are selected by the writing address supplied from the input-output interface 11. The writing/reading circuit 15 controls all the bit lines Yj. In the following description, the first word line Xi(1), the second word line Xi(2), and the third word line Xi(3) that are selected by the writing address are referred to as a first word line Xiw(1), a second word line Xiw(2), and a third word line Xiw(3), respectively.

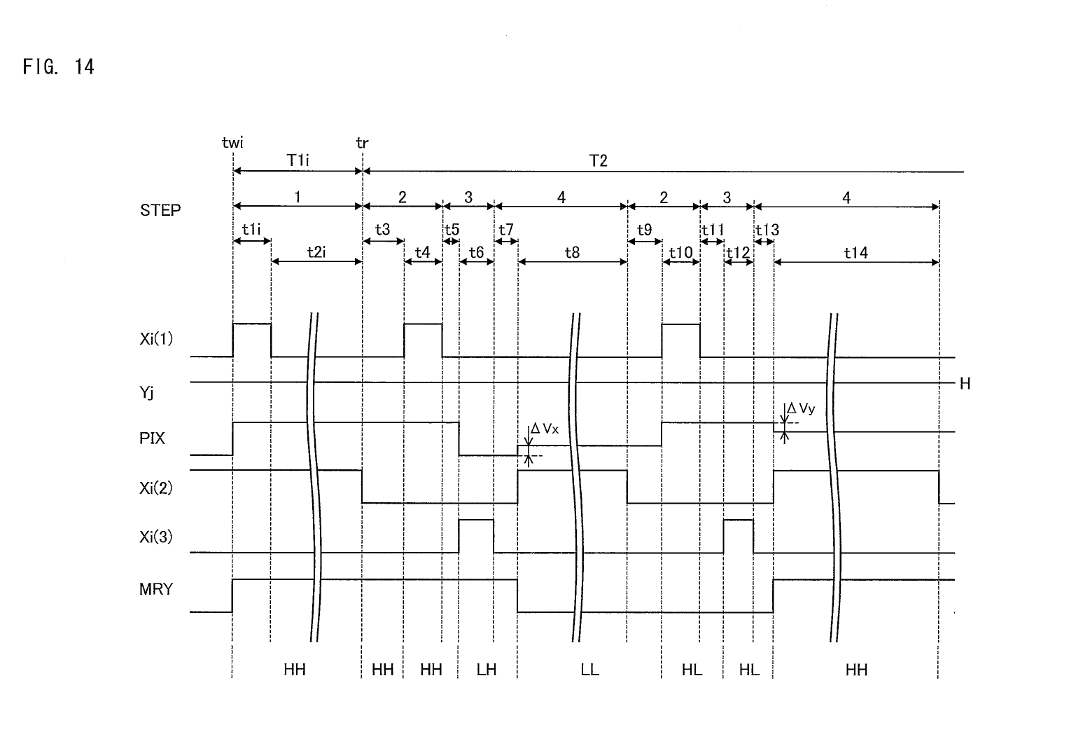

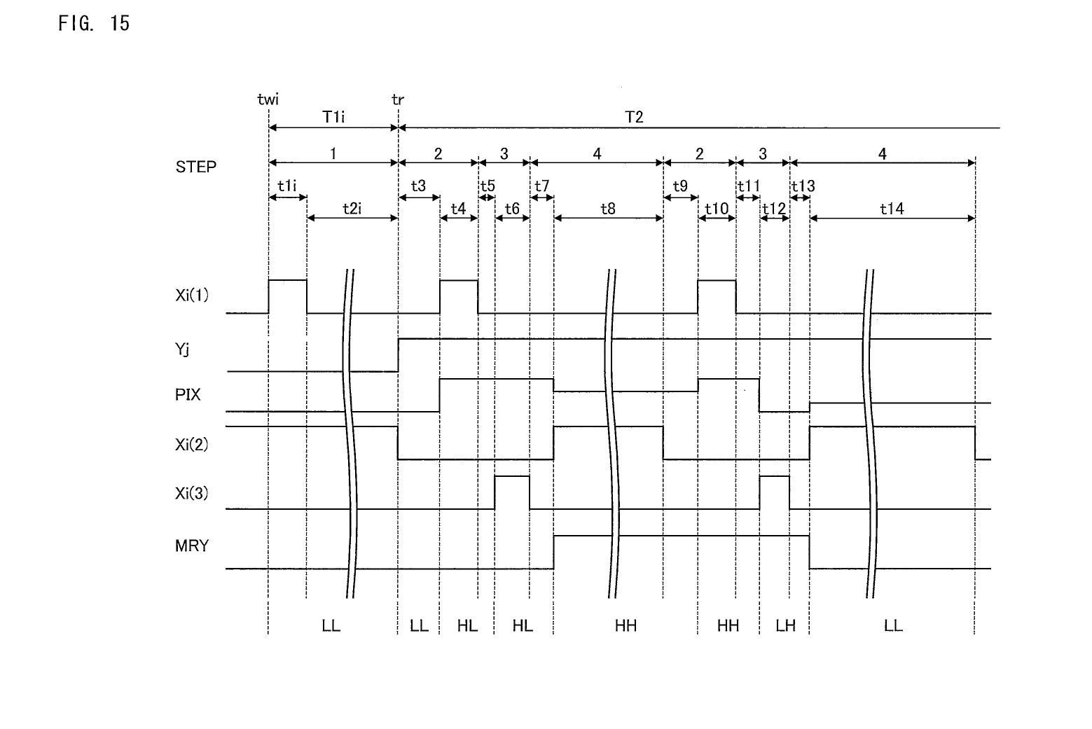

FIG. 14 and FIG. 15 illustrate the data writing operation of the memory circuit MR1. In the present Example, in a case where any data is written into memory circuits MR1 of respective different rows, the rows of the memory array 10 which correspond to the writing address are line-sequentially driven. Accordingly, a writing period T1 is determined for each row, and a writing period T1 of an i-th row is referred to as T 11. FIG. 14 illustrates a case where High as the first electric potential level is written in the writing period T1i, and FIG. 15 illustrates a case where Low as the second electric potential level is written in the writing period T1i. In addition, lower portions of FIG. 14 and FIG. 15 illustrate an electric potential of the node PIX (left side) and an electric potential of the node MRY (right side) in periods corresponding to (a) through (h) of FIG. 23.

In FIG. 14, an electric potential of binary levels which are High (active level) and Low (non-active level) is applied from the word line control circuit 14 to the first word line Xiw(1), the second word line Xiw(2), and the third word line Xiw(3). The electric potential of the binary levels, i.e., the High electric potential and the Low electric potential may be set individually for each of the lines. To the bit line Yj, binary logic levels which are High lower than the High electric potential of the first word line Xiw(1) and Low are supplied from the writing/reading circuit 15. The High electric potential of the second word line Xiw(2) is equal to the High electric potential of the bit line Yj or the High electric potential of the first word line Xi(1), and the Low electric potential of the second word line Xiw(2) is equal to the Low electric potential of the binary logic levels. The reference electric potential wire RL1 supplies a constant electric potential.

For the data writing operation, the writing period T1i and the refresh period T2 are provided. The writing period T1i starts at a time twi which is determined for each row. The refresh period T2 starts at a time tr simultaneously for all the rows including rows which do not correspond to the writing address, after the writing of data into the memory circuits MR1 of the rows corresponding to the writing address is finished. The writing period T1i is a period in which a binary logic level corresponding to data to be retained in the memory circuit MR1 is written and which is made up of successive periods t1i and t2i. The refresh period T2 is a period in which the binary logic level written into the memory circuit MR1 is retained while being refreshed and which has successive periods t3 through t14.

In the period t1i of the writing period T1i, both of the electric potential of the first word line Xiw(1) and the electric potential of the second word line Xiw(2) are High. The electric potential of the third word line Xiw(3) is Low. This causes the transistors N1 and N2 to turn on, which causes the switching circuit SW1 to be in a conductive state and causes the data transfer section TS1 to be in a state in which the data transfer section TS1 carries out the transfer operation. Thus, the first electric potential level (here High) supplied to the bit line Yj is written into the node PIX. In the period t2i, the electric potential of the first word line Xiw(1) becomes Low, whereas the electric potential of the second word line Xiw(2) maintains High. The electric potential of the third word line Xiw(3) is Low. This causes the transistor N1 to turn off, which causes the switching circuit SW1 to be in a non-conductive state. Since the transistor N2 maintains the ON state, the data transfer section TS1 maintains the state in which the data transfer section TS1 carries out the transfer operation. Accordingly, the first electric potential level is transferred from the node PIX to the node MRY, and the nodes PIX and MRY are disconnected from the bit line Yj. The above process corresponds to the state in (a) of FIG. 23.

Next, the refresh period T2 starts. In the refresh period T2, the electric potential of the bit line Yj is High which is the first electric potential level. As for the first word line Xi(1), the second word line Xi(2), and the third word line Xi(3), driving described below is carried out for all the values of i (1≦i≦n). That is, the refresh operation is carried out simultaneously for all the memory cells 20 (this may be hereinafter referred to as “entire refresh operation”).

In the period t3 of the refresh period T2, the electric potential of the first word line Xi(1) is Low, the electric potential of the second word line Xi(2) is Low, and the electric potential of the third word line Xi(3) is Low. This causes the transistor N2 to turn off, which causes the data transfer section TS1 to be in a state in which the data transfer section TS1 carries out the non-transfer operation. Thus, the node PIX and the node MRY are disconnected from each other. Both of the node PIX and the node MRY maintain High. The above process corresponds to the state in (b) of FIG. 23.

In the period t4, the electric potential of the first word line Xi(1) becomes High, the electric potential of the second word line Xi(2) maintains Low, and the electric potential of the third word line Xi(3) maintains Low. This causes the transistor N1 to turn on, which causes the switching circuit SW1 to be in a conductive state. Thus, the High electric potential is written into the node PIX from the bit line Yj again.

In the period t5, the electric potential of the first word line Xi(1) becomes Low, the electric potential of the second word line Xi(2) maintains Low, and the electric potential of the third word line Xi(3) maintains Low. This causes the transistor N1 to turn off, which causes the switching circuit SW1 to be in a non-conductive state. Thus, the node PIX is disconnected from the bit line Yj, and maintains High.

The process in the period t4 through the period t5 corresponds to the state in (c) of FIG. 23.

In the period t6, the electric potential of the first word line Xi(1) maintains Low, the electric potential of the second word line Xi(2) maintains Low, and the electric potential of the third word line Xi(3) becomes High. This causes the transistor N4 to turn on, which causes the refresh output control section RS1 to carry out the first operation. Since the electric potential of the node MRY is High, the transistor N3 is in an ON state. Accordingly, the refresh output control section RS1 is in an active state, and a Low electric potential is supplied from the second word line Xi(2) via the transistors N3 and N4 to the node PIX. The second word line Xi(2) also functions as the voltage supply VS1 in FIG. 22.

In the period t7, the electric potential of the first word line Xi(1) maintains Low, the electric potential of the second word line Xi(2) maintains Low, and the electric potential of the third word line Xi(3) becomes Low. This causes the transistor N4 to turn off, which causes the refresh output control section RS1 to carry out the second operation. The node PIX is disconnected from the second word line Xi(2), and maintains Low.

The process in the period t6 through the period t7 corresponds to the state in (d) of FIG. 23.

In the period t8, the electric potential of the first word line Xi(1) maintains Low, the electric potential of the second word line Xi(2) becomes High, and the electric potential of the third word line Xi(3) maintains Low. This causes the transistor N2 to turn on, which causes the data transfer section TS1 to be in a state in which the data transfer section TS1 carries out the transfer operation. Here, movement of an electric charge occurs between the capacitor Ca1 and the capacitor Cb1. This causes both of the electric potential of the node PIX and the electric potential of the node MRY to be Low. The electric potential of the node PIX rises by a slight voltage ΔVx due to movement of a positive electric charge from the capacitor Cb1 to the capacitor Ca1 via the transistor N2, but falls within a range of a Low electric potential.

The period t8 is a period in which refreshed binary logic data is retained in both of the first data retaining section DS1 and the second data retaining section DS2 which are connected to each other via the data transfer section TS1, and the period t8 can be set long. The same is true for the Examples and Embodiments below.

In the period t9, the electric potential of the first word line Xi(1) maintains Low, the electric potential of the second word line Xi(2) becomes Low, and the electric potential of the third word line Xi(3) maintains Low. This causes the transistor N2 to turn off, which causes the data transfer section TS1 to be in a state in which the data transfer section TS1 carries out the non-transfer operation. The node PIX and the node MRY are disconnected from each other. Both of the node PIX and the node MRY maintain Low. The process in the period t8 through the period t9 corresponds to the state in (e) of FIG. 23.

In the period t10, the electric potential of the first word line Xi(1) becomes High, the electric potential of the second word line Xi(2) maintains Low, and the electric potential of the third word line Xi(3) maintains Low. This causes the transistor N1 to turn on, which causes the switching circuit SW1 to be in a conductive state. Thus, the High electric potential is written to the node PIX from the bit line Yj again.

In the period t11, the electric potential of the first word line Xi(1) becomes Low, the electric potential of the second word line Xi(2) maintains Low, and the electric potential of the third word line Xi(3) maintains Low. This causes the transistor N1 to turn off, which causes the switching circuit SW1 to be in a non-conductive state. Thus, the node PIX is disconnected from the bit line Yj, and maintains High.

The process in the period t10 through the period t11 corresponds to the state in (f) of FIG. 23.

In the period t12, the electric potential of the first word line Xi(1) maintains Low, the electric potential of the second word line Xi(2) maintains Low, and the electric potential of the third word line Xi(3) becomes High. This causes the transistor N4 to turn on, which causes the refresh output control section RS1 to be in a state in which the refresh output control section RS1 carries out the first operation. Since the electric potential of the node MRY is Low, the transistor N3 is in an OFF state. This causes the refresh output control section RS1 to be in a non-active state, in which the refresh output control section RS1 stops carrying out the output. Accordingly, the node PIX maintains High.

In the period t13, the electric potential of the first word line Xi(1) maintains Low, the electric potential of the second word line Xi(2) maintains Low, and the electric potential of the third word line Xi(3) becomes Low. This causes the transistor N4 to turn off, which causes the refresh output control section RS1 to be in a state in which the refresh output control section RS1 carries out the second operation. The node PIX maintains High.

The process in the period t12 through the period t13 corresponds to the state in (g) of FIG. 23.

In the period t14, the electric potential of the first word line Xi(1) maintains Low, the electric potential of the second word line Xi(2) becomes High, and the electric potential of the third word line Xi(3) maintains Low. This causes the transistor N2 to turn on, which causes the data transfer section TS1 to be in a state in which the data transfer section TS1 carries out the transfer operation. Here, movement of an electric charge occurs between the capacitor Ca1 and the capacitor Cb1. This causes both of the electric potential of the node PIX and the electric potential of the node MRY to be High. The electric potential of the node PIX declines by a slight voltage ΔVy due to movement of a positive electric charge from the capacitor Ca1 to the capacitor Cb1 via the transistor N2, but falls within a range of a High electric potential. The above process corresponds to the state in (h) of FIG. 23.

The period t14 is a period in which refreshed binary logic data is retained in both of the first data retaining section DS1 and the second data retaining section DS2 which are connected to each other via the data transfer section TS1, and the period t14 can be set long. The same is true for the Examples and Embodiments below.

As a result of the above operation, the electric potential of the node PIX is High in the period t11 through the period t5 and the period t10 through the period t14 and is Low in the period t6 through the period t9, and the electric potential of the node MRY is High in the period t1i through the period t7 and the period t14 and is Low in the period t8 through the period t13.

Thereafter, in a case where the refresh period T2 is continued, the command decoder 12 repeats the operation in the period t3 through the period t14. In a case where new data is written or the data is read out, the command decoder 12 finishes the refresh period T2 so as to terminate the entire refresh operation mode.

The above description has discussed the case of FIG. 14.

Note that it is also possible that the command for the entire refresh operation is generated not from an externally supplied signal but from a clock which is internally generated by an oscillator or the like. This makes it unnecessary for an external system to supply a refresh command at regular time intervals, thereby producing an advantage of allowing flexible system construction. In a dynamic memory circuit using the memory cell 20 according to the present Example, it is unnecessary to carry out the entire refresh operation by performing scan for each word line, and the entire refresh operation can be carried out simultaneously for an entire array. This eliminates the need for a peripheral circuit which is necessary, in a general conventional dynamic memory circuit, for refreshing an electric potential of a bit line Yj while performing destructive read.

Next, the following discusses the case of FIG. 15.

In FIG. 15, Low as the second electric potential level is written into the memory cell 20 in the writing period T1i. However, in FIG. 7, the electric potentials of the first word line Xi(1), the second word line Xi(2), and the third word line Xi(3) are changed in the periods in a similar manner to FIG. 14 except for that the electric potential of the bit line Yj is Low in the writing period T1i.

Accordingly, the electric potential of the node PIX is Low in the period t1i through the period t3 and the period t12 through the period t14 and is High in the period t4 through the period t11, and the electric potential of the node MRY is Low in the period t1i through the period t7 and the period t14 and is High in the period t8 through the period t13.

Although (a) through (h) of FIG. 23 illustrate transition of the state of the memory cell 20, the operation of the memory circuit MR1 in FIG. 14 and FIG. 15 can be classified into the following operation steps.

(1) First Step (the Period T1i Through the Period t2i (the Writing Period t1i))

In the first step, a state is achieved in which (i) a binary logic level corresponding to data is being supplied from the writing/reading circuit 15 to the bit line Yj and (ii) the refresh output control section RS1 is carrying out the second operation. In the state, the switching circuit SW1 is made conductive, which allows the binary logic level to be written into the memory cell 20. Then, in a state in which (i) the binary logic level is being written into the memory cell 20 and (ii) the refresh output control section RS1 is carrying out the second operation, the data transfer section TS1 carries out the transfer operation.

(2) Second Step (Each of the Period t3 Through the Period t4 and the Period t9 Through the Period t10)

In the second step following the first step, a state is achieved in which (i) the refresh output control section RS1 is carrying out the second operation and (ii) the data transfer section TS1 is carrying out the non-transfer operation. In the state, the switching circuit SW1 is made conductive. This causes a binary logic level same as a level equivalent to control information which causes the refresh output control section RS1 to be in an active state to be supplied to the first data retaining section DS1 via the bit line Yj.

(3) Third Step (Each of the Period t5 Through the Period t6 and the Period T11 Through the Period t12)

In the third step following the second step, a state is achieved in which (i) the switching circuit SW1 is being made non-conductive and (ii) the data transfer section TS1 is carrying out the non-transfer operation. In the state, the refresh output control section RS1 carries out the first operation. At the end of the first operation, a state is achieved in which a binary logic level reverse to a level equivalent to control information which causes the refresh output control section RS1 to be in an active state is supplied from the voltage supply VS1 to the input of the refresh output control section RS1.

(4) Fourth Step (Each of the Period t7 Through the Period t8 and the Period t13 Through the Period t14)

In the fourth step following the third step, a state is achieved in which (i) the switching circuit SW1 is being made non-conductive and (ii) the refresh output control section RS1 is carrying out the second operation. In the state, the data transfer section TS1 carries out the transfer operation.

As for the whole writing operation, the first step is executed first and, subsequently to the first step, the series of the operations from the start of the second step to the end of the fourth step (the period t3 through the period t8) is executed at least once.

Next, the reading operation of the memory circuit MR1 is described.

The reading operation is carried out as follows. Specifically, the input-output interface 11 receives a reading command and a reading address from an outside of the memory device 1 via a transmission line, and the command decoder 12 interprets the command and shifts into a reading mode. In accordance with a signal indicative of the reading mode of the command decoder 12, the timing generating circuit 13 generates an internal timing signal for the reading operation. The word line control circuit 14 controls a first word line Xi(1), a second word line Xi(2), and a third word line Xi(3) that are selected by the reading address supplied from the input-output interface 11. The writing/reading circuit 15 controls all the bit lines Yj. In the following description, the first word line Xi(1), the second word line Xi(2), and the third word line Xi(3) that are selected by the reading address are referred to as a first word line Xir(1), a second word line Xir(2), and a third word line Xir(3), respectively.

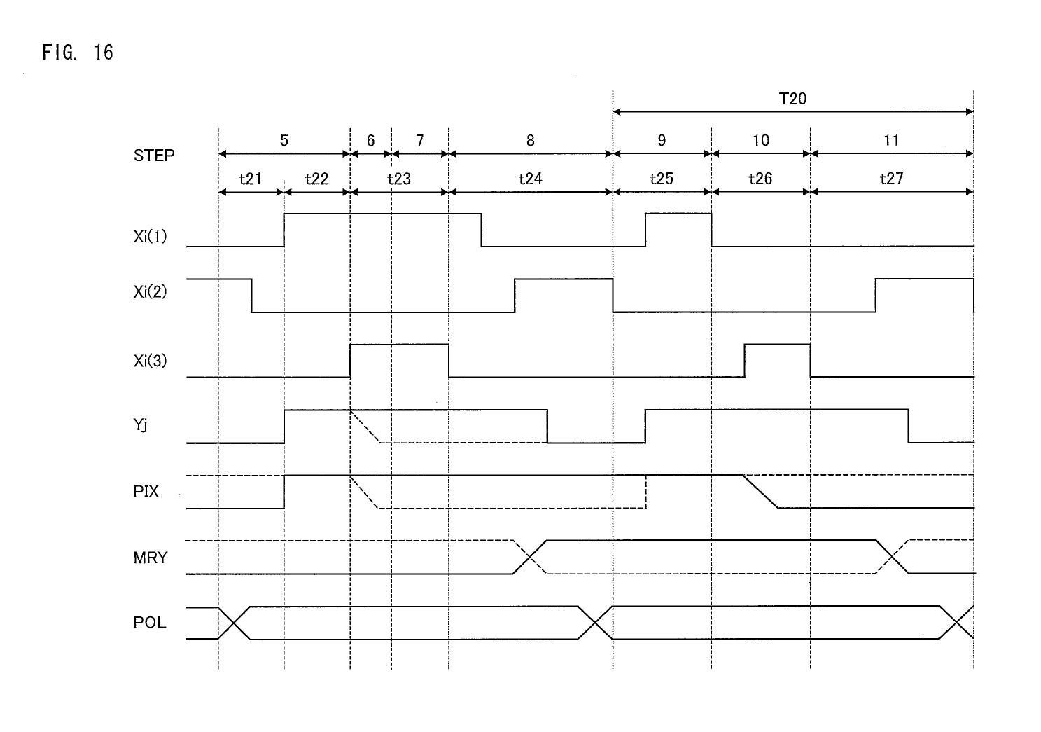

The operation of the memory cell 20 is described with reference to FIG. 16.

FIG. 16 illustrates electric potential waveforms of the first word line Xir(1), the second word line Xir(2), the third word line Xir(3), each bit line Yj, the node PIX, and the node MRY, and a waveform of a polarity signal POL.

The polarity signal POL is an internal signal indicative of a polarity of data retained in the node PIX. In the memory cell 20 of the present embodiment, the electric potential of the node PIX is level-reversed from High to Low or Low to High every time the refresh operation is carried out. Accordingly, a polarity of current data of the memory cell 20 is retained with the use of the polarity signal POL. That is, a polarity of the polarity signal POL is reversed every refresh operation. Thus, even in a case where a data polarity is reversed every refresh, it is possible to correctly read whether data written at a certain timing is “0” or “1”. The polarity signal POL may be controlled by the writing/reading circuit 15 or may be controlled by the timing generating circuit 13.

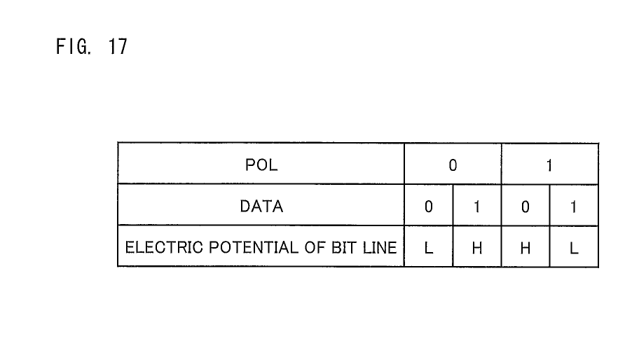

FIG. 17 shows one example of how the polarity signal POL, data, and the electric potential of the bit line Yj are related with each other. The polarity signal POL is switched between “0” and “1” every time the data is retained in the memory cell 20 and refreshed. For example, it is assumed that data written into the memory cell 20 in a case where the polarity signal POL is 0 is “0” and a binary logic level supplied corresponding to the data is “L”. In this case, a binary logic level of “L” is retained in the memory cell 20 in a case where the polarity signal POL is “0”, whereas a binary logic level of “H” is retained in the memory cell 20 in a case where the polarity signal POL is “1”.

In the reading mode, a first set period t21, a pre-charge period t22, a sense period t23, a second set period t24, and a refresh period T20 are provided in this order. The refresh period T20 may be executed simultaneously for all the rows corresponding to the reading address after successive operations in the first set period t21, the pre-charge period t22, the sense period t23, and the second set period t24 are carried out sequentially for each of the rows corresponding to the reading address. Alternatively, successive operations in the first set period t21, the pre-charge period t22, the sense period t23, the second set period t24, and the refresh period T20 may be carried out sequentially for each of the rows corresponding to the reading address.

When the reading mode starts, the first set period t21 starts first in which the polarity of the polarity signal POL is reversed, and then the electric potential of the second word line Xir(2) is made Low.

Next, the pre-charge period t22 starts in which the electric potential of the first word line Xir(1) is made High, and electric potentials of all the bit lines Yj are made High (binary logic level same as a level equivalent to control information which causes the refresh control section RS1 to be in an active state during the first operation). Further, the writing/reading circuit 15 causes all the bit lines Yj to be in a high impedance state.

Next, the sense period t23 starts in which the electric potential of the third word line Xir(3) is made High. This causes the transistor N4 to turn on, which causes the refresh output control section RS1 to be in a state in which the refresh output control section RS1 carries out the first operation. Here, in a case where an electric potential retained in the node MRY is High, the refresh output control section RS1 is in an active state, and the transistor N3 is turned on. This causes a positive electric charge of the bit line Yj to be discharged into the second word line Xir(2), thereby making the bit line Yj Low (see the broken line in FIG. 16). Meanwhile, in a case where the electric potential retained in the node MRY is Low, the refresh output control section RS1 is in a non-active state, and the transistor N3 is turned off. Accordingly, the bit line Yj maintains the High electric potential (see the solid line in FIG. 16).

Accordingly, data of a selected address can be read by causing the writing/reading circuit 15 to sense an electric potential of each bit line Yj and by determining output data in accordance with the polarity signal POL as shown in FIG. 17. The data thus read is supplied to an outside by the input-output interface 11. At the end of the sense period t23, the electric potential of the third word line Xir(3) is made Low, and the transistor N4 is turned off, thereby causing the refresh output control section RS1 to be in a state in which the refresh output control section RS1 carries out the second operation.

Next, the second set period t24 starts. In the second set period t24, first, the electric potential of the first word line Xir(1) is made Low. This causes the transistor N1 to turn off, i.e., causes the switching circuit SW1 to be in a non-conductive state. Subsequently, in this state, the electric potential of the second word line Xir(2) is made High, so that the transistor N2 is turned on. This causes the data transfer section TS1 to be in a state in which the data transfer section TS1 carries out the transfer operation, and causes the node PIX and the node MRY to be connected to each other. Thus, a binary logic level is transferred from the node PIX to the node MRY. Accordingly, a data polarity of the node MRY becomes identical to a data polarity of the node PIX. As a result, a state in achieved in which the data polarities retained in the nodes PIX and MRY before the reading are reversed. Subsequently, the electric potential of each bit line Yj is made Low by the writing/reading circuit 15. Before the end of the second set period t24, the polarity of the polarity signal POL is reversed.

Next, the refresh period T20 starts. In the refresh period T20, only a word line corresponding to a selected address is controlled so that refresh operation of only 1 address is carried out. Thus, the polarities of the nodes PIX and MRY which have been reversed by the reading operation are returned to the original polarities. In the refresh period T20, similar operation to the refresh operation in the writing mode described with reference to FIG. 14 and FIG. 15 is carried out.

First, the period t25 starts in which the electric potential of the second word line Xir(2) becomes Low. This causes the transistor N2 to turn off, which causes the data transfer section TS1 to be in a state in which the data transfer section TS1 carries out the non-transfer operation. Next, the electric potential of the first word line Xir(1) becomes High, and an electric potential of each bit line Yj is made High by the writing/reading circuit 15. This change in electric potential of the bit line Yj may be made from the start of the refresh period t25, as in FIG. 14 and FIG. 15. This causes the transistor N1 to turn on, i.e., causes the switching circuit SW1 to be in a conductive state. Thus, the electric potential of the node PIX becomes High.

Next, the period t26 starts in which the electric potential of the third word line Xir(3) becomes High. This causes the transistor N4 to turn on, i.e., causes the refresh output control section RS1 to be in a state in which the refresh output control section RS1 carries out the first operation. Here, in a case where the electric potential of the node MRY is High, the transistor N3 is in an ON state. This causes the refresh output control section RS1 to be in an active state. Accordingly, the node PIX is charged to Low which is the electric potential of the second word line Xir(2). Meanwhile, in a case where the electric potential of the node MRY is Low, the transistor N3 is in an OFF state. This causes the refresh output control section RS1 to be in a non-active state. Accordingly, the node PIX maintains the High electric potential.

Next, the period t27 starts in which the electric potential of the third word line Xir(3) becomes Low. This causes the transistor N4 to turn off, i.e., causes the refresh output control section RS1 to be in a state in which the refresh output control section RS1 carries out the second operation. Subsequently, the electric potential of the second word line Xir(2) becomes High. This causes the transistor N2 to turn on, i.e., causes the data transfer section TS1 to be in a state in which the data transfer section TS1 carries out the transfer operation. Thus, data of the node PIX is transferred to the node MRY, thereby causing the nodes PIX and MRY to be refreshed to identical polarities to the electric potentials obtained immediately before the reading. An electric potential of each bit line Yj is returned to Low. Before the end of the period t27, the polarity of the polarity signal POL is reversed.

This period in which the electric potential of the second word line Xir(2) is High out of the period t27 is a period in which refreshed binary logic data is retained in both of the first data retaining section DS1 and the second data retaining section DS2 that are connected to each other via the data transfer section TS1, and this period can be set long as in the case of the writing operation. This stabilizes the electric potentials of the nodes PIX and MRY. Consequently, an operation error is less likely to occur in the memory cell 20.

The refresh operation of the memory cell 20 corresponding to the reading address may end after the operation in the period T20 is executed once or subsequently the same operation as that executed in the period T20 may be repeated. In a case where the same refresh operation is repeated, the electric potential polarities of the nodes PIX and MRY are reversed once every time the refresh operation is carried out once.

In the reading mode, data is read in a state in which the capacitor of the bit line Yj is sufficiently charged. Accordingly, in restoring data after the reading, it is unnecessary to provide a peripheral circuit which is necessary, in a general conventional dynamic memory circuit, for refreshing an electric potential of a bit line while performing destructive read.

The operation of the memory circuit MR1 in FIG. 16 can be classified into the following operation steps.

(1) Fifth Step (the Period t21 Through the Period t22)

In the fifth step, a state in achieved in which (i) a binary logic level that is same as a level equivalent to the control information which causes the refresh output control section RS1 to be in an active state is being supplied from the writing/reading circuit 15 to the bit line Yj, (ii) the data transfer section TS1 is carrying out the non-transfer operation, and (iii) the refresh output control section RS1 is carrying out the second operation. In the state, the switching circuit SW1 is made conductive. Thus, the binary logic level is written into the memory cell 20.

(2) Sixth Step (the Period t23)

In the sixth step following the fifth step, a state is achieved in which (i) the switching circuit SW1 is being made conductive and (ii) the data transfer section TS1 is carrying out the non-transfer operation. In the state, the refresh output control section RS1 carries out the first operation.

(3) Seventh Step (the Period t23)

In the seventh step following the sixth step, a state is achieved in which (i) the switching circuit SW1 is being made conductive and (ii) the data transfer section TS1 is carrying out the non-transfer operation. In the state, the writing/reading circuit 15 senses the electric potential of the bit line Yj. Thus, data retained in the memory cell 20 is determined.

(4) Eighth Step (the Period t24)

In the eighth step following the seventh step, a state is achieved in which (i) the switching circuit SW1 is being made non-conductive and (ii) the refresh output control section RS1 is carrying out the second operation. In the state, the data transfer section TS1 carries out the transfer operation.

(5) Ninth Step (the Period t25)

In the ninth step following the eighth step, a state is achieved in which (i) the data transfer section TS1 is carrying out the non-transfer operation, (ii) a binary logic level that is same as a level equivalent to the control information which causes the refresh output control section RS1 to be in an active state is being supplied from the writing/reading circuit 15 to the bit line Yj, and (iii) the refresh output control section RS1 is carrying out the second operation. In the state, the switching circuit SW1 is made conductive.

(6) Tenth Step (the Period t26)

In the tenth step following the ninth step, a state is achieved in which (i) the switching circuit SW1 is being made non-conductive and (ii) the data transfer section TS1 is carrying out the non-transfer operation. In the state, the refresh output control section RS1 carries out the first operation.

(7) Eleventh Step (the Period t27)

In the eleventh step following the tenth step, a state is achieved in which (i) the switching circuit SW1 is being made non-conductive and (ii) the refresh output control section RS1 is carrying out the second operation. In the state, the data transfer section TS1 carries out the transfer operation.

As for the whole reading operation, the fifth step through the eighth step are executed first and, subsequently to the eighth step, the series of the operations from the start of the ninth step to the end of the eleventh step (the period t25 through the period t27 (the refresh period T20)) is executed at least once.

The following describes a modification of the present Example.

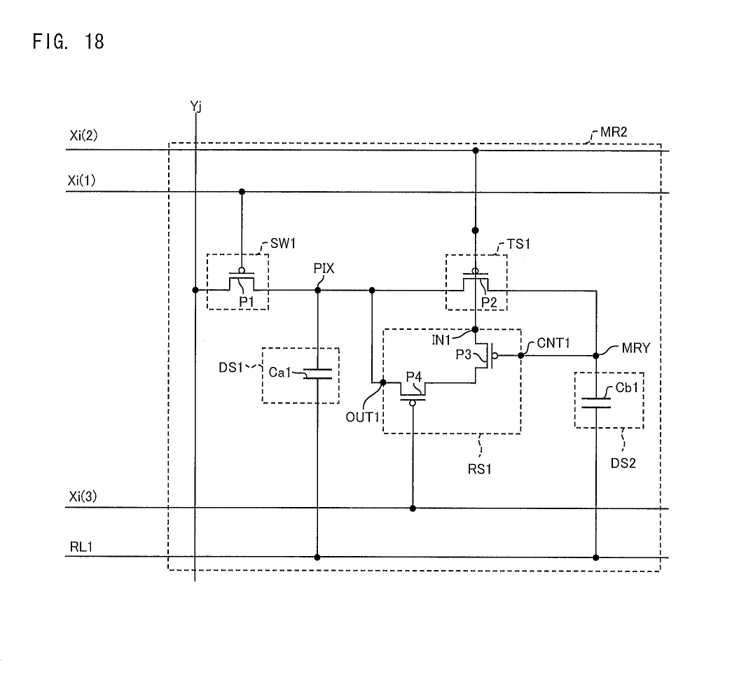

FIG. 18 illustrates an arrangement of a memory cell 20 of the modification in the form of a memory circuit MR2 which is an equivalent circuit.

As described above, the memory circuit MR2 includes a switching circuit SW1, a first data retaining section DS1, a data transfer section TS1, a second data retaining section DS2, and a refresh output control section RS1.

The switching circuit SW1 includes a transistor P1 which is a P-channel TFT in replacement of the transistor N1 of FIG. 13. The data transfer section TS1 includes a transistor (third switch) P2 which is a P-channel TFT in replacement of the transistor N2 of FIG. 13. The refresh output control section RS1 includes a transistor (first switch) P3 which is a P-channel TFT in replacement of the transistor N3 of FIG. 13 and a transistor (second switch) P4 which is a P-channel TFT in replacement of the transistor N4 of FIG. 13. The first data retaining section DS1 and the second data retaining section DS2 have identical arrangements to those in FIG. 13.

That is, in FIG. 18, all the transistors constituting the memory circuit are P-channel TFTs (field-effect transistors).

In a state in which the transistor P1 is on, the switching circuit SW1 is in a conductive state, whereas in a state in which the transistor P1 is off, the switching circuit SW1 is in a non-conductive state. In a state in which the transistor P2 is on, the data transfer section TS1 is in a state in which the data transfer section TS1 carries out the transfer operation, whereas in a state in which the transistor P2 is off, the data transfer section TS1 is in a state in which the data transfer section TS1 carries out the non-transfer operation.

In a state in which the transistor P4 is on, the refresh output control section RS1 is controlled to be a state in which the refresh output control section RS1 carries out the first operation. Meanwhile, in a state in which the transistor P4 is off, the refresh output control section RS1 is controlled to be a state in which the refresh output control section RS1 carries out the second operation. Since the transistor P3 is a P-channel TFT, control information which causes the refresh output control section RS1 to be in an active state during the first operation, i.e., an active level is Low, and control information which causes the refresh output control section RS1 to be in a non-active state during the first operation, i.e., a non-active level is High.

As wires for driving each memory circuit MR2, the memory device 1 includes a reference electric potential wire RL1 in addition to the first word line Xi(1), the second word line Xi(2), the third word line Xi(3), and the bit line Yj as in FIG. 13. However, driving waveforms of these wires are different from those in FIG. 14 and FIG. 15, and are therefore described below.

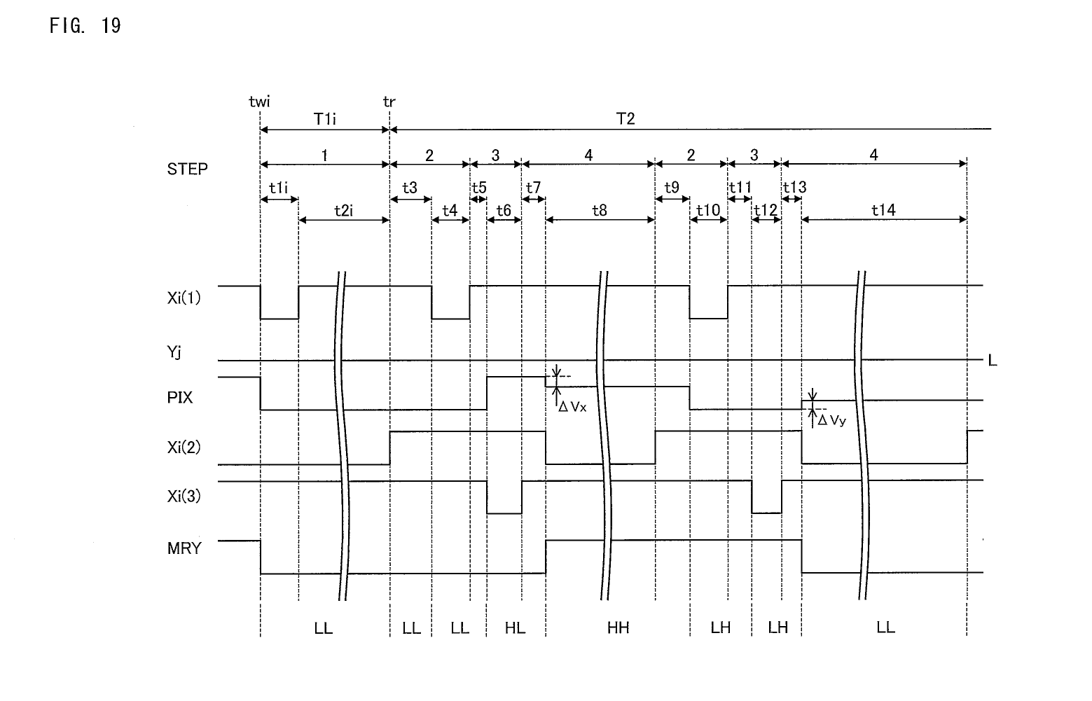

FIG. 19 explains a writing operation of the memory circuit MR2.

In FIG. 19, the electric potential waveforms (High or Low) of the first word line Xi(1), the second word line Xi(2), and the third word line Xi(3) are reverse to those of FIG. 14. It is, for example, assumed that an electric potential written into the memory circuit MR2 via the bit line Yj in the period t1i is Low. It is assumed that the electric potential of the bit line Yj in the period T2 is Low.

As a result, the electric potential waveforms of the node PIX and the node MRY are reverse to those of FIG. 14 with respect to a middle level between High and Low.

Accordingly, the electric potential of the node PIX is Low in the period t1i through the period t5 and the period t10 through the period t14 and is High in the period t6 through the period t9, and the electric potential of the node MRY is Low in the period t1i through the period t7 and the period t14 and is High in the period t8 through the period t13.

In a case where an electric potential written into the memory circuit MR2 via the bit line Yj in the period t1i is High, the electric potential waveforms of the node PIX and the node MRY are reverse to those of FIG. 15 with respect to a middle level between High and Low (not shown).

Accordingly, the electric potential of the node PIX is High in the period t1i through the period t3 and the period t12 through the period t14 and Low in the period t4 through the period t11, and the electric potential of the node MRY is High in the period t1i through the period t7 and the period t14 and Low in the period t8 through the period t13.

The reading operation of the memory circuit MR2 is carried out by reversing the electric potential waveforms of the first word line Xi(1), the second word line Xi(2), and the third word line Xi(3) between High and Low in FIG. 16 (not shown).

[Description of Display Device]

A display device of the present invention is described below with reference to FIG. 24 through FIG. 26.

The following describes a display device which includes the memory device 1 that has been described so far.

FIG. 24 illustrates an arrangement of a liquid crystal display device 3 as the display device. The liquid crystal display device 3 is switched between (i) a multi-gradation display mode, which is for example used for screen display during an operation mode of a mobile phone, and (ii) a memory circuit operation mode, which is for example used for screen display during a standby mode of the mobile phone.

The liquid crystal display device 3 includes a pixel array 31, a gate driver/CS driver 32, a control signal buffer circuit 33, a driving signal generating circuit/video signal generating circuit 34, a demultiplexer 35, a gate line (scanning signal line) GL(i), an auxiliary capacitor wire CS(i), a data transfer control line DT1(i), a refresh output control line RC1(i), a source line (data signal line) SL(j), and an output signal line vd(k). Note that i is an integer (1≦i≦n), j is an integer (1≦j≦m), and k is an integer (1≦k≦l≦m).

The pixel array 31 is arranged such that pixels 40 each represented by a pixel circuit MR9 are provided in a matrix. In the pixel array 31, an image is displayed. Each of the pixels 40 includes the memory cell 20. Accordingly, the pixel array 31 includes the memory array 10.

The gate driver/CS driver 32 is a driving circuit which drives pixels 40 corresponding to n rows via the gate line GL(i) and the auxiliary capacitor wire CS(i). The gate line GL(i) and the auxiliary capacitor wire CS(i) are connected to each pixel 40 of an i-th row. The gate line GL(i) functions also as the switch control line SC1 (FIG. 22), i.e., the first word line Xi(1). The auxiliary capacitor wire CS(i) functions also as the reference electric potential wire RL1.

The control signal buffer circuit 33 is a driving circuit which drives the pixels 40 corresponding to the n rows via the data transfer control line DT1(i) and the refresh output control line RC1(i). The data transfer control line DT1(i) is the data transfer control line DT1 (FIG. 22), i.e., the second word line Xi(2). The refresh output control line RC1(i) is the refresh output control line RC1, i.e., the third word line Xi(3).

The driving signal generating circuit/video signal generating circuit 34 is a control driving circuit for performing image display and memory operation. The driving signal generating circuit/video signal generating circuit 34 includes the input-output interface 11, the command decoder 12, the timing control circuit 13, and the writing/reading circuit 15 in FIG. 20 in addition to a display data processing circuit. The timing control circuit 13 is capable of functioning also as a circuit which generates not only a timing used for the memory operation, but also timings such as a gate start pulse, a gate clock, a source start pulse, and a source clock which are used for display operation.

During the multi-color display mode (memory circuit non-operation mode), the driving signal generating circuit/video signal generating circuit 34 outputs a multi-gradation video signal from a video output terminal so as to drive the source line SL(j) via the output signal line vd(k) and the demultiplexer 35. Concurrently with this, the driving signal generating circuit/video signal generating circuit 34 outputs a signal s1 for driving/controlling the gate driver/CS driver 32. This allows display data to be written into each of the pixels 40 and allows a multi-gradation moving image/still image to be displayed.

During the memory circuit operation mode, the driving signal generating circuit/video signal generating circuit 34 supplies data to be retained in the pixels 40 from the video output terminal to the source line SL(j) via the output signal line vd(k) and the demultiplexer 35. In addition, the driving signal generating circuit/video signal generating circuit 34 supplies a signal s2 for driving/controlling the gate driver/CS driver 32 and a signal s3 for driving/controlling the control signal buffer circuit 33. This allows data to be written into the pixels 40 so that the data is displayed or retained and allows the data retained in the pixels 40 to be read.

Note, however, that the reading operation from the pixels 40 need not necessarily be carried out since the data which has been written into the pixels 40 and is retained in a memory circuit may be used only for display. The data supplied from the video output terminal to the output signal line vd(k) by the driving signal generating circuit/video signal generating circuit 34 during the memory circuit operation mode is a binary logic level indicated by a first electric potential level and a second logic level. In a case where a pixel 40 corresponds to each picture element for color display, an image can be displayed with colors as many as 2 to the power of the number of colors of the picture elements. For example, in a case where picture elements of three colors (R, G, and B) exist, display can be carried out in display modes of 8 colors (2 to the power of 3). The demultiplexer 35 distributes, to corresponding source lines SL(j), the data supplied to the output signal line vd(k).

As is clear from the above description, the gate driver/CS driver 32 and the control signal buffer circuit 33 constitute a row driver. Meanwhile, the driving signal generating circuit/video signal generating circuit 34 and the demultiplexer 35 constitute a column driver.

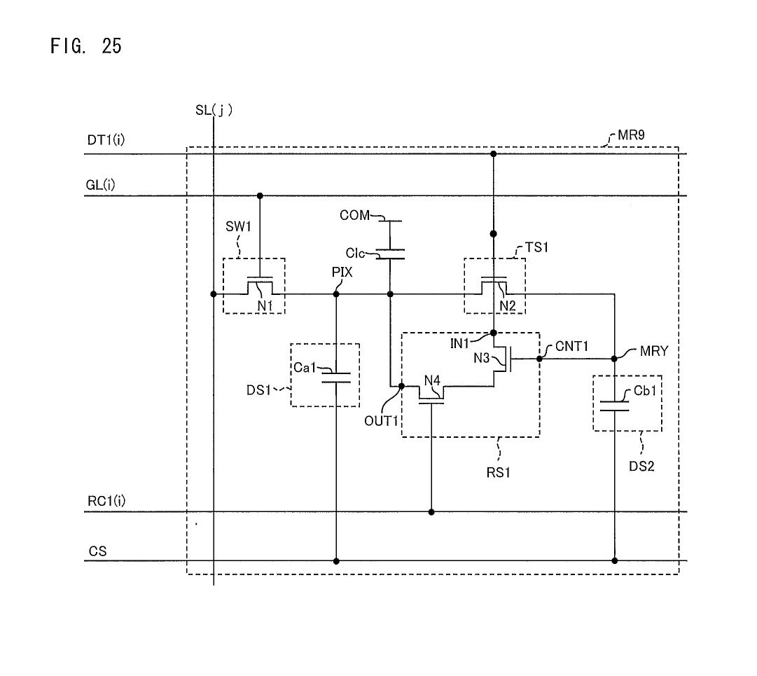

Next, FIG. 25 illustrates an example of an arrangement of the pixel 40 in the form of a pixel circuit MR9 which is an equivalent circuit.

The pixel circuit MR9 is arranged such that a liquid crystal capacitor C1c is added to the memory circuit MR1 of FIG. 13. Note that the first word line Xi(1), the second word line Xi(2), the third word line Xi(3), and the bit line Yj in FIG. 13 are illustrated as the gate line GL(i), the data transfer control line DT1(i), the refresh output control line RC1(i), and the source line SL(j), respectively.

The liquid crystal capacitor C1c is a capacitor which includes a liquid crystal layer disposed between a node PIX and a common electrode COM. That is, the node PIX is connected to a pixel electrode. The capacitor Ca1 functions also as an auxiliary capacitor of the pixel 40. The transistor N1 which constitutes the switching circuit SW1 functions also as a selection element of the pixel 40. The common electrode COM is provided on a common electrode substrate facing a matrix substrate on which the circuit of FIG. 24 is formed. Note, however, that the common electrode COM may be provided on the matrix substrate.

All of the above-mentioned memory circuits can be used as a memory circuit provided in the pixel circuit MR9.

During the multi-gradation display mode, in the pixel circuit MR9, a data signal with the larger number of electric potential levels than binary levels is supplied to the pixel 40. Thus, display is carried out in a state in which the refresh control section RS1 does not carry out the first operation in which the refresh control section RS1 is in the active state. During the multi-gradation display mode, the electric potential of the data transfer control line DT1(i) may be fixed to Low so that only the capacitor Ca1 functions as an auxiliary capacitor or the electric potential of the data transfer control line DT1(i) may be fixed to High so that the capacitor Ca1 and the capacitor Cb1 function as an auxiliary capacitor. Further, the electric potential of the refresh output control line RC1(i) is fixed to Low so that the transistor N4 maintains an OFF state or the electric potential of the data transfer control line DT1(i) is set high so that the transistor N3 turns off. This prevents the electric potential of the data transfer control line DT1 from affecting a display gradation of the liquid crystal capacitor C1c which display gradation is determined by an electric charge accumulated in the first data retaining section DS1. Consequently, it is possible to achieve display performance identical to that of a liquid crystal display device having no memory function.

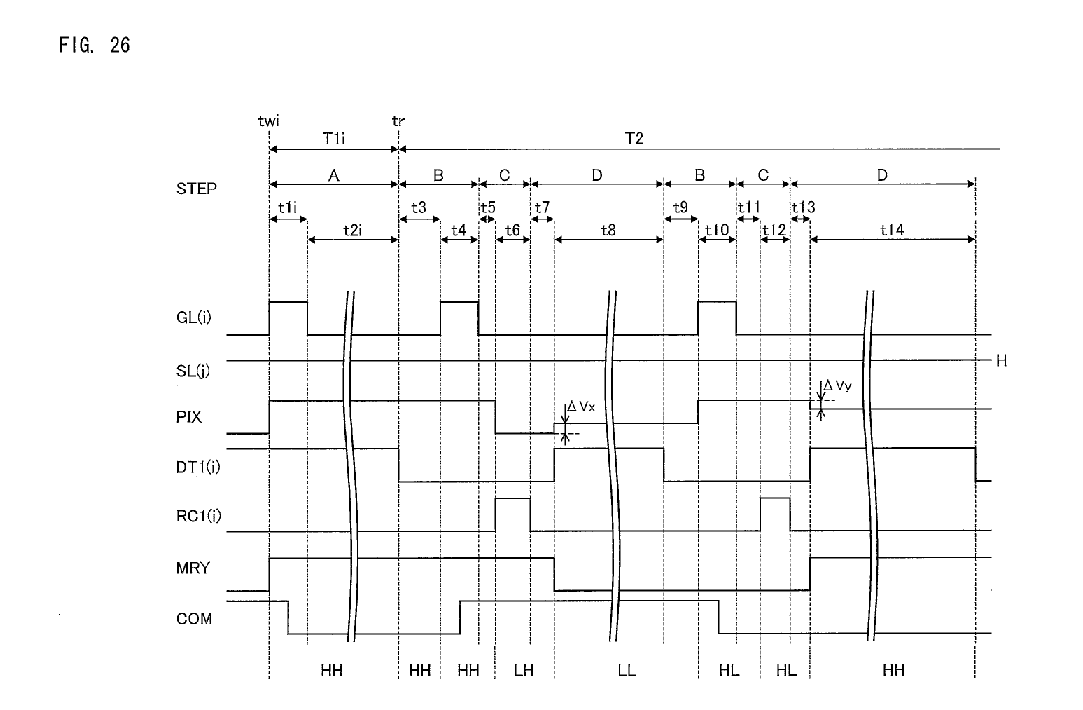

FIG. 26 illustrates operation of the pixel circuit MR9 during the memory circuit operation mode. In the memory circuit operation mode of FIG. 26, an electric potential waveform of the common electrode COM is added to the electric potential waveforms of FIG. 14. That is, the memory circuit operation mode is executed by using the writing operation into the memory cell 20 in the memory device 1.

The operation of the pixel circuit MR9 in FIG. 26 can be classified into the following operation steps.

(1) Step A (the Period t11 Through the Period t2i (the Writing Period T1i))

In the step A, a state is achieved in which (i) a binary logic level corresponding to a data signal is being supplied from the driving signal generating circuit/video signal generating circuit 34 and the demultiplexer 35 to the source line SL(j) and (ii) the refresh output control section RS1 is carrying out the second operation. In the state, the switching circuit SW1 is made conductive. This allows the binary logic level to be written into the pixel 40. Then, in a state in which (i) the binary logic level is being written into the memory cell 20 and (ii) the refresh output control section RS1 is carrying out the second operation, the data transfer section TS1 carries out the transfer operation.

(2) Step B (Each of the Period t3 Through the Period t4 and the Period t9 Through the Period t10)

In the step B following the step A, a state is achieved in which (i) the refresh output control section RS1 is carrying out the second operation and (ii) the data transfer section TS1 is carrying out the non-transfer operation. In the state, the switching circuit SW1 is made conductive. Thus, a binary logic level which is same as a level equivalent to the control information which causes the refresh output control section RS1 to be in an active state is supplied to the first data retaining section DS1 via the source line SL(j).

(3) Step C (Each of the Period t5 Through the Period t6 and the Period t11 Through the Period t12)

In the step C following the step B, a state is achieved in which (i) the switching circuit SW1 is being made non-conductive and (ii) the data transfer section TS1 is carrying out the non-transfer operation. In the state, the refresh output control section RS1 carries out the first operation. At the end of the first operation, a state is achieved in which a binary logic level which is reverse to a level equivalent to the control information which causes the refresh output control section RS1 to be in an active state is supplied from the data transfer control line DT1(i), which functions also as the voltage supply VS1, to the input of the refresh output control section RS1.

(4) Step D (Each of the Period t7 Through the Period t8 and the Period t13 Through the Period t14)

In the step D following the step C, a state is achieved in which (i) the switching circuit SW1 is being made non-conductive and (ii) the refresh output control section RS1 is carrying out the second operation. In the state, the data transfer section TS1 carries out the transfer operation.

As for the whole operation during the memory circuit operation mode, the step A is executed first, and subsequently to the step A, the series of operations from the start of the step B to the end of the step D (the period t3 through the period t8) is executed at least once.

The common electrode COM is driven so that an electric potential of the common electrode COM is reversed between High and Low every time the transistor N1 turns on. By thus carrying out inversion AC drive of the common electrode of the liquid crystal capacitor so that the electric potential of the common electrode is reversed between the binary levels, bright and dark can be displayed while carrying out AC drive of the liquid crystal capacitor so that a polarity of an applied voltage is alternated between a positive polarity and a negative polarity.

It is, for example, assumed that the binary levels supplied to the common electrode COM are a first electric potential level and a second electric potential level. This makes it possible to easily achieve black display and white display only by the first electric potential level and the second electric potential level in both of a case where a voltage applied to liquid crystals is of a positive polarity and a case where the voltage applied to the liquid crystals is of a negative polarity. For example, assume that the High electric potential of the common electrode COM is equal to the High electric potential of the binary logic levels and that the Low electric potential of the common electrode COM is equal to the Low electric potential of the binary logic levels. In a case where the electric potential of the common electrode COM is Low and where the electric potential of the node PIX is Low, black display of a positive polarity is achieved, whereas in a case where the electric potential of the common electrode COM is Low and where the electric potential of the node PIX is High, white display of a positive polarity is achieved. In a case where the electric potential of the common electrode COM is High and where the electric potential of the node PIX is Low, white display of a negative polarity is achieved, whereas in a case where the electric potential of the common electrode COM is High and where the electric potential of the node PIX is High, black display of a negative polarity is achieved. Accordingly, the liquid crystals are driven so that a direction of the voltage applied to the liquid crystals is reversed every time the electric potential of the node PIX is refreshed, while keeping an almost identical display gradation. This allows AC driving of the liquid crystals in which an effective value of the voltage applied to the liquid crystals is constant regardless of whether the voltage is positive or negative.

Further, it is, for example, assumed that the binary level supplied to the common electrode COM is reversed only in a period in which the switching circuit SW1 is conductive as shown in FIG. 26. Since the binary level supplied to the common electrode COM is reversed only in a period in which the pixel electrode is connected to the source line SL(j) via the switching circuit SW1, the common electrode electric potential is reversed in a state in which the pixel electrode electric potential is fixed to an electric potential of the source line SL(j). This prevents the pixel electrode electric potential that is being retained, especially the pixel electrode electric potential in a refresh period from changing, for example, due to the reversal of the common electrode electric potential in a floating state of the node PIX.

As described above, according to the present embodiment, the display device can have both of the function of the multi-gradation display mode (second display mode) and the function of the memory circuit operation mode (first display mode). During the memory circuit operation mode, in which an image, such as a still image, which hardly changes with time is displayed, circuits such as an amplifier for displaying a multi-gradation image in a video signal generating circuit and data supply operation can be stopped. This allows low power consumption. In addition, during the memory circuit operation mode, an electric potential can be refreshed within the pixel 40. This makes it unnecessary to rewrite data of the pixel 40 while charging/discharging the source line SL(j) again, thereby allowing a reduction in power consumption. Furthermore, a data polarity can be reversed within the pixel 40. This makes it unnecessary to, at the time of polarity reversal, overwrite the data with display data whose polarity has been reversed while charging/discharging the source line SL(j). This allows a reduction in power consumption.

The pixel circuit MR9 serving as a memory circuit does not have a factor which greatly increases power consumption such as a through current of an inverter for carrying out a refresh operation. This makes it possible to greatly reduce power consumption of the memory circuit operation mode itself, as compared with a conventional art.

A display device can be configured to include the memory device 1 so that the memory circuit MR is disposed within a driving circuit such as a CS driver of the display device. In such a case, for example, a binary logic level of retained data is used as an output directly from a memory cell. Use of the memory circuit MR1 of FIG. 13, in which all the transistors are N-channel TFTs, allows the memory cell to be formed in a driving circuit that is monolithically built into a display panel made of amorphous silicon.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

The present invention is suitably applicable to a display of a mobile phone, and the like.

### REFERENCE SIGNS LIST

1: Memory device
3: Liquid crystal display device (display device)
10: Memory array
14: Word line control circuit 14 (row driver)
15: Writing/reading circuit (column driver)
20: Memory cell
tx: Predetermined period
SC1: Switch control line (first wire)
DT1: Data transfer control line (second wire)
RC1: Refresh output control line (third wire)
IN1: Data input line (fourth wire)
Xi(1) (1≦i≦n): First word line (first wire)
Xi(2) (1≦i≦n): Second word line (second wire, voltage supply)
Xi(3) (1≦i≦n): Third word line (third wire)
Yj (1≦j≦m): Bit line (fourth wire)
DS1: First data retaining section (first retaining section)
DS2: Second data retaining section (second retaining section)
TS1: Data transfer section (transfer section)
RS1: Refresh output control section (first control section)
VS1: Voltage supply
L1, L2: Control line (voltage supply)
GL(i) (1≦i≦n): Gate line (scanning signal line)
SL(j) (1≦j≦m): Source line (data signal line)

1. A memory device comprising:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section, and
a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

2. A memory device comprising:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and
a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

3. A memory device comprising:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section, and
a predetermined period being set in which in a state where the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

4. A memory device comprising:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and
a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

5. A display device comprising a memory device as set forth in claim 1,
the first retaining section including a liquid crystal capacitor whose pixel electrode is connected to a retaining node which retains the binary logic level of the first retaining section,
the first wire functioning also as a scanning signal line and the fourth wire functioning also as a data signal line, and
the display device carrying out display by application of a voltage to the liquid crystal capacitor that is applied by causing the row driver to drive the switching circuit via the first wire and by supplying a data signal from the column driver via the fourth wire and the switching circuit to the first retaining section.

6. A method for driving a memory device,
the memory device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section, and
a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

7. A method for driving a memory device,
the memory device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and
a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

8. A method for driving a memory device,
the memory device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section, and
a predetermined period being set in which in a state in which the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

9. A method for driving a memory device,
the memory device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive, and
a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

10. A method for driving a display device,
the display device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section,
the first retaining section including a liquid crystal capacitor whose pixel electrode is connected to a retaining node which retains the binary logic level of the first retaining section,
the first wire functioning also as a scanning signal line and the fourth wire functioning also as a data signal line,
the display device carrying out display by application of a voltage to the liquid crystal capacitor that is applied by causing the row driver to drive the switching circuit via the first wire and by supplying a data signal from the column driver via the fourth wire and the switching circuit to the first retaining section, and
a predetermined period being set in which in a state where the first control section turns off the output element, (i) the first retaining section and the second retaining section retain an identical binary logic level, (ii) an electric potential of the voltage supply is set to one of the first electric potential level and the second electric potential level, (iii) the other one of the first electric potential level and the second electric potential level is supplied from the column driver to the fourth wire, and (iv) subsequently the fourth wire is shifted to a floating state.

11. A method for driving a display device,
the display device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive,
the first retaining section including a liquid crystal capacitor whose pixel electrode is connected to a retaining node which retains the binary logic level of the first retaining section,
the first wire functioning also as a scanning signal line and the fourth wire functioning also as a data signal line,
the display device carrying out display by application of a voltage to the liquid crystal capacitor that is applied by causing the row driver to drive the switching circuit via the first wire and by supplying a data signal from the column driver via the fourth wire and the switching circuit to the first retaining section, and
a predetermined period being set in which in a state where the first control section turns off the output element, (i) the first retaining section and the second retaining section retain an identical binary logic level, (ii) an electric potential between the first electric potential level and the second electric potential level is supplied from the column driver to the fourth wire, and (iii) subsequently the fourth wire is shifted to a floating state.

12. A method for driving a display device,
the display device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section; and
a voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first control section determining, in accordance with the binary logic level retained in the second retaining section, whether or not an electric potential supplied from the voltage supply is transferred to an output element of the first control section via a connecting element, the output element of the first control section that is connected to the first retaining section being driven via the third wire so as to be conductive or non-conductive,
the voltage supply supplying a set electric potential to the first control section,
the first retaining section including a liquid crystal capacitor whose pixel electrode is connected to a retaining node which retains the binary logic level of the first retaining section,
the first wire functioning also as a scanning signal line and the fourth wire functioning also as a data signal line,
the display device carrying out display by application of a voltage to the liquid crystal capacitor that is applied by causing the row driver to drive the switching circuit via the first wire and by supplying a data signal from the column driver via the fourth wire and the switching circuit to the first retaining section, and
a predetermined period being set in which in a state where the first control section turns off the output element, (i) the first retaining section and the second retaining section retain an identical binary logic level, (ii) an electric potential of the voltage supply is set to one of the first electric potential level and the second electric potential level, and (iii) the other one of the first electric potential level and the second electric potential level continues to be supplied from the column driver to the fourth wire.

13. A method for driving a display device,
the display device including:
a memory array in which memory cells are provided in a matrix pattern;
a row driver which drives each row of the memory array;
a column driver which drives each column of the memory array;
a first wire which is provided for the each row and which is connected to memory cells in an identical row;
a second wire and a third wire each of which is connected to the memory cells in the identical row;
and a fourth wire which is provided for the each column and which is connected to memory cells in an identical column, the fourth wire being driven by the column driver so that each of a first electric potential level and a second electric potential level each indicating a binary logic level is supplied to the fourth wire,
the memory cells of the memory array each including:
a switching circuit;
a first retaining section;
a transfer section;
a second retaining section;
a first control section;
a first voltage supply; and
a second voltage supply,
the switching circuit being driven by the row driver via the first wire, so as to select conduction/non-conduction between the fourth wire and the first retaining section,
the first retaining section retaining the binary logic level to be supplied thereto,
the transfer section being driven via the second wire, so as to selectively carry out (i) a transfer operation in which the binary logic level retained in the first retaining section is transferred to the second retaining section while being retained in the first retaining section and (ii) a non-transfer operation in which no transfer operation is carried out,
the second retaining section retaining the binary logic level to be supplied thereto,
the first voltage supply supplying the first electric potential level to the first control section,
the second voltage supply supplying the second electric potential level to the first control section,
the first control section (i) transferring the second electric potential level supplied from the second voltage supply to an output element of the first control section via a connecting element, in a case where the binary logic level retained in the second retaining section is the first electric potential level, and (ii) transferring the first electric potential level supplied from the first voltage supply to the output element of the first control section via the connecting element, in a case where the binary logic level retained in the second retaining section is the second electric potential level, the output element of the first control section that is connected to the first retaining section being driven via the third wire so as to be conductive or non-conductive,
the first retaining section including a liquid crystal capacitor whose pixel electrode is connected to a retaining node which retains the binary logic level of the first retaining section,
the first wire functioning also as a scanning signal line and the fourth wire functioning also as a data signal line,
the display device carrying out display by application of a voltage to the liquid crystal capacitor that is applied by causing the row driver to drive the switching circuit via the first wire and by supplying a data signal from the column driver via the fourth wire and the switching circuit to the first retaining section, and
a predetermined period being set in which in a state where the first control section turns off the output element, (i) the first retaining section and the second retaining section retain an identical binary logic level, and (ii) an electric potential between the first electric potential level and the second electric potential level continues to be supplied from the column driver to the fourth wire.

14. A display device comprising a memory device as set forth in claim 2,
the first retaining section including a liquid crystal capacitor whose pixel electrode is connected to a retaining node which retains the binary logic level of the first retaining section,
the first wire functioning also as a scanning signal line and the fourth wire functioning also as a data signal line, and
the display device carrying out display by application of a voltage to the liquid crystal capacitor that is applied by causing the row driver to drive the switching circuit via the first wire and by supplying a data signal from the column driver via the fourth wire and the switching circuit to the first retaining section.

15. A display device comprising a memory device as set forth in claim 3,
the first retaining section including a liquid crystal capacitor whose pixel electrode is connected to a retaining node which retains the binary logic level of the first retaining section,
the first wire functioning also as a scanning signal line and the fourth wire functioning also as a data signal line, and
the display device carrying out display by application of a voltage to the liquid crystal capacitor that is applied by causing the row driver to drive the switching circuit via the first wire and by supplying a data signal from the column driver via the fourth wire and the switching circuit to the first retaining section.

16. A display device comprising a memory device as set forth in claim 4,
the first retaining section including a liquid crystal capacitor whose pixel electrode is connected to a retaining node which retains the binary logic level of the first retaining section,
the first wire functioning also as a scanning signal line and the fourth wire functioning also as a data signal line, and
the display device carrying out display by application of a voltage to the liquid crystal capacitor that is applied by causing the row driver to drive the switching circuit via the first wire and by supplying a data signal from the column driver via the fourth wire and the switching circuit to the first retaining section.
